(19) United States
(12) Patent Application Publication
(10) Pub. No.: US 2026/0182287 A1
(43) Pub. Date: Jun. 25, 2026

(54) METHOD OF MANUFACTURING CHIP AND DIVIDING DEVICE

(71) Applicant: DISCO CORPORATION, Tokyo (JP)

(72) Inventor: Fumiya SATO, Tokyo (JP)

(21) Appl. No.: 19/407,447

(22) Filed: Dec. 3, 2025

(30) Foreign Application Priority Data
Dec. 23, 2024 (JP) 2024-226505
Oct. 9, 2025 (JP) 2025-171151

(51) Int. Cl. H10P 54/00; H10P 52/00; H10P 72/70

(52) U.S. Cl. CPC H10P 54/00; H10P 52/00; H10P 72/7402; H10P 72/7416

(57) ABSTRACT

A method of manufacturing a chip by dividing a wafer, includes first and second division steps. The first step includes pressing, while clamping a first region of a wafer unit by a clamper, a second region of the wafer unit from a back surface side of the wafer or from a front surface side. The wafer unit includes the wafer and a sheet fixed to a back surface of the wafer. The first region of the wafer unit is on one side of a first planned division line of the wafer. The second region is on the opposite side of the first planned division line. The second division step includes pressing the second region of the wafer unit from the back surface side or from the front surface side different from that in the first division step, while clamping the first region of the wafer unit by the clamper.

### CROSS-REFERENCE TO RELATED APPLICATION(S)

The present application claims priority to and incorporates by reference the entire contents of Japanese Patent Application No. 2024-226505 filed in Japan on December 23, 2024 and Japanese Patent Application No. 2025-171151 filed in Japan on October 9, 2025.

### TECHNICAL FIELD

The present disclosure relates to a method of manufacturing a chip and a dividing device.

### BACKGROUND

A wafer on which a metal layer that is a ductile material layer is formed is known. A braking device that divides such a wafer along division starting points such as grooves and modified layers is used (See, for example, JP 2024-027963 A).

When such a wafer is divided along division starting points such as grooves or modified layers, the metal layer may not be divided, or burrs may be generated.

For this reason, it is required to stably divide the metal layer without impairing the quality.

### SUMMARY OF THE INVENTION

A method of manufacturing a chip according to an aspect of the present disclosure is for manufacturing a chip by dividing a wafer having division starting points formed along planned division lines for sectioning a chip region where the chip is formed, along the planned division lines. The method includes a first division step and a second division step performed after the first division step. The first division step includes pressing, while clamping a first region of a wafer unit by a clamper along a first planned division line of the planned division lines, a second region of the wafer unit along the first planned division line from a back surface side of the wafer or from a front surface side opposite to the back surface side. The wafer unit includes the wafer and a sheet fixed to a back surface of the wafer. The first region is on one side of the first planned division line. The second region is on an opposite side of the first planned division line. The second division step includes pressing the second region of the wafer unit along the first planned division line from the back surface side or from the front surface side that is different from that in the first division step, while clamping the first region of the wafer unit by the clamper along the first planned division line.

A method of manufacturing a chip according to another aspect of the present disclosure is for manufacturing a chip by dividing a wafer having division starting points formed along planned division lines for sectioning a chip region where the chip is formed, along the planned division lines. The method includes a first division step and a second division step performed after the first step. The first division step includes pressing, while clamping a first region of a wafer unit by a clamper along a first planned division line of the planned division lines, a second region of the wafer unit the first planned division line along the first planned division line from a back surface side of the wafer or from a front surface side opposite to the back surface side along the first planned division line. The wafer unit includes the wafer and a sheet fixed to a back surface of the wafer. The first region is on one side of the first planned division line. The second region is on an opposite side of the first planned division line. The second division step includes: clamping the second region of the wafer unit by a pair of pressing bars, while clamping the first region of the wafer unit by the clamper along the first planned division line; and relatively moving the clamper and the pair of pressing bars in a thickness direction of the wafer.

A dividing device according to still another aspect of the present disclosure includes a fixing unit, a detection unit, a pair of clamping bars, a first pressing bar, and a second pressing bar. The fixing unit fixes a wafer unit. The wafer unit includes a wafer in which planned division lines for sectioning a chip region are set and a sheet fixed to the wafer. The detection unit detects the planned division lines of the wafer of the wafer unit fixed by the fixing unit. The pair of clamping bars clamps a first region of the wafer unit along a first planned division line of the planned division lines detected by the detection unit. The first region is on one side of the first planned division line. The first pressing bar presses a second region of the wafer unit along the first planned division line from a front surface side. The second region is on an opposite side of the first planned division line. The second pressing bar is a component different from the first pressing bar and presses the second region of the wafer unit along the first planned division line from a side opposite to the front surface side.

A dividing device according to still another aspect of the present disclosure includes a fixing unit, a detection unit, a pair of clamping bars, a pressing bar, and a reversing unit. The fixing unit fixes a wafer unit. The wafer unit includes a wafer in which planned division lines for sectioning a chip region are set and a sheet fixed to the wafer. The detection unit detects the planned division lines of the wafer of the wafer unit fixed by the fixing unit. The pair of clamping bars clamps a first region of the wafer unit along a first planned division line of the planned division lines detected by the detection unit. The first region is on one side of the first planned division line. The pressing bar presses a second region of the wafer unit along the first planned division line. The second region being on an opposite side of the first planned division line. The reversing unit reverses the wafer unit.

### BRIEF DESCRIPTION OF THE DRAWINGS

FIG. 1 is a perspective view schematically illustrating a configuration example of a braking device according to a first embodiment;

FIG. 2 is a perspective view schematically illustrating a wafer unit including wafers to be divided by the braking device illustrated in FIG. 1;

FIG. 3 is a cross-sectional view schematically illustrating a main part in a state in which a division starting point is formed in the wafer illustrated in FIG. 2;

FIG. 4 is a side view schematically illustrating a configuration of the braking device illustrated in FIG. 1 in a partial cross section;

FIG. 5 is a perspective view schematically illustrating a configuration of a lower clamping unit of a clamping unit of the braking device illustrated in FIG. 1;

FIG. 6 is a side view schematically illustrating a configuration of an upper clamping unit of the clamping unit of the braking device illustrated in FIG. 1, in a partial cross section;

FIG. 7 is a side view schematically illustrating a pressing bar of the braking device illustrated in FIG. 1 in a partial cross section;

FIG. 8 is a front view schematically illustrating a load measuring unit viewed from a direction of an arrow VIII illustrated in FIG. 7 in a partial cross section;

FIG. 9 is a flowchart illustrating a flow of a method of manufacturing a chip according to the first embodiment;

FIG. 10 is a diagram schematically illustrating a main part in a state where the wafer is clamped between clamping members in a first division step of the method of manufacturing a chip illustrated in FIG. 9 in a partial cross section;

FIG. 11 is a side view schematically illustrating, in a partial cross section, the configuration of the upper clamping unit in a state where a distance between a first pressing bar and an upper clamping member is adjusted in the first division step of the method of manufacturing a chip illustrated in FIG. 9;

FIG. 12 is a diagram schematically illustrating the main part in a state where the first pressing bar presses the wafer in the first division step of the method of manufacturing a chip illustrated in FIG. 9 in a partial cross section;

FIG. 13 is a side view schematically illustrating, in a partial cross section, the configuration of the upper clamping unit in a state where the first pressing bar is brought close to the upper clamping member in a third division step of the method of manufacturing a chip illustrated in FIG. 9;

FIG. 14 is a diagram schematically illustrating, in a partial cross section, the main part in a state where the first pressing bar is brought close to the upper clamping member in the third division step of the method of manufacturing a chip illustrated in FIG. 9;

FIG. 15 is a diagram schematically illustrating, in a partial cross section, the main part in a state where the first pressing bar is lowered in the third division step of the method of manufacturing a chip illustrated in FIG. 9;

FIG. 16 is a diagram schematically illustrating a main part of a second division step of the method of manufacturing a chip illustrated in FIG. 9 in a partial cross section;

FIG. 17 is a diagram schematically illustrating a main part of an expanding step of the method of manufacturing a chip illustrated in FIG. 9 in a partial cross section;

FIG. 18 is a diagram schematically illustrating a configuration example of a braking device according to a second embodiment;

FIG. 19 is a flowchart illustrating a flow of a method of manufacturing a chip according to the second embodiment;

FIG. 20 is a diagram schematically illustrating a main part of a second division step of the method of manufacturing a chip illustrated in FIG. 19 in a partial cross section;

FIG. 21 is a diagram schematically illustrating, in a partial cross section, a main part in a state where the wafer is clamped between pressing bars in a second division step of the method of manufacturing a chip according to a first modification;

FIG. 22 is a diagram schematically illustrating, in a partial cross section, a main part in a state where the wafer is pressed in a second division step of the method of manufacturing a chip according to the first modification;

FIG. 23 is a diagram schematically illustrating, in a partial cross section, a main part in a state where the wafer is clamped between pressing bars in a second division step of the method of manufacturing a chip according to the second modification;

FIG. 24 is a diagram schematically illustrating, in a partial cross section, a main part in a state where the wafer is pressed in the second division step of the method of manufacturing a chip according to the second modification;

FIG. 25 is a diagram schematically illustrating, in a partial cross section, a main part in a state where the wafer is clamped between pressing bars in a second division step of a method of manufacturing a chip according to a third modification;

FIG. 26 is a diagram schematically illustrating, in a partial cross section, a main part in a state where the wafer is pressed in the second division step of the method of manufacturing a chip according to the third modification;

FIG. 27 is a diagram schematically illustrating, in a partial cross section, a main part in a state where the wafer is clamped between pressing bars in a second division step of the method of manufacturing a chip according to a fourth modification;

FIG. 28 is a diagram schematically illustrating, in a partial cross section, a main part in a state where the clamping member is moved and the wafer is pressed by the pressing bar in the second division step of the method of manufacturing a chip according to the fourth modification;

FIG. 29 is a diagram schematically illustrating, in a partial cross section, a main part in a state where the wafer is clamped between pressing bars in a second division step of a method of manufacturing a chip according to a fifth modification; and

FIG. 30 is a diagram schematically illustrating, in a partial cross section, a main part in a state where the clamping member is moved and the wafer is pressed by the pressing bar in the second division step of the method of manufacturing a chip according to the fifth modification.

### DETAILED DESCRIPTION OF THE PREFERRED EMBODIMENTS

An embodiment of the present invention will be described in detail with reference to the drawings. The present invention is not limited by the contents described in the following embodiment. In addition, the components described below include those that can be easily assumed by those skilled in the art and those that are substantially the same. Furthermore, the configurations described below can be appropriately combined. In addition, various omissions, substitutions, or changes in the configuration can be made without departing from the gist of the present invention.

### First Embodiment

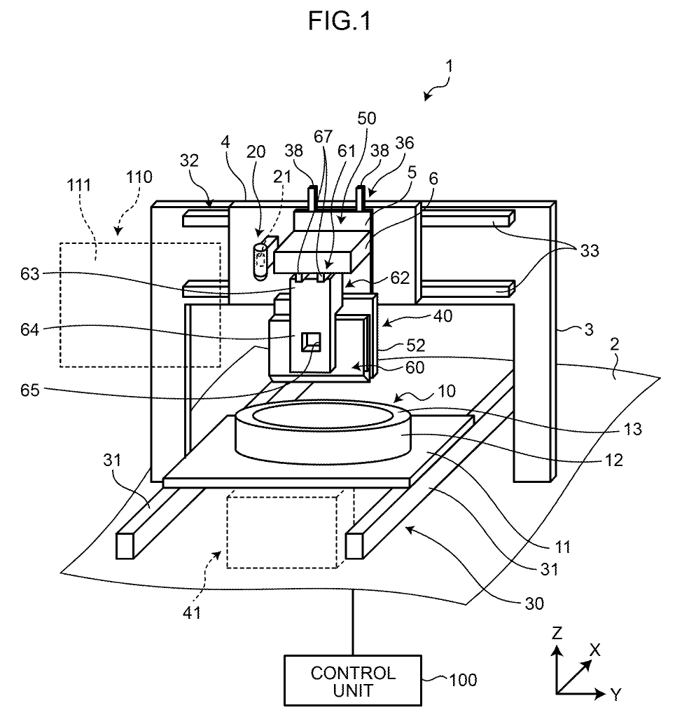

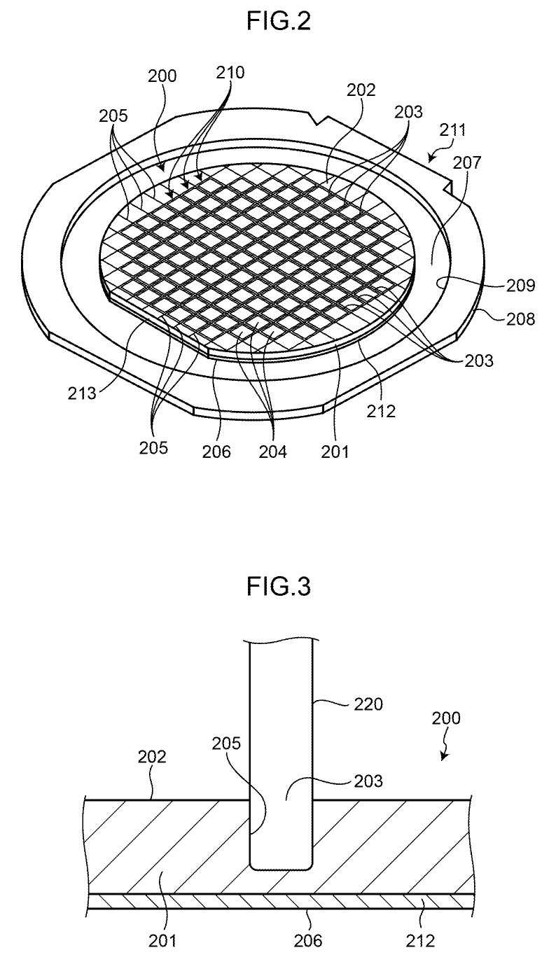

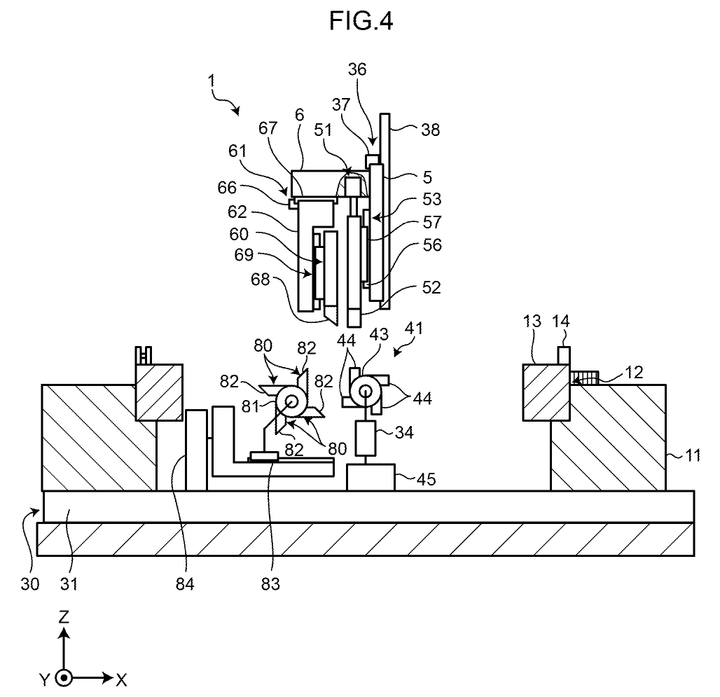

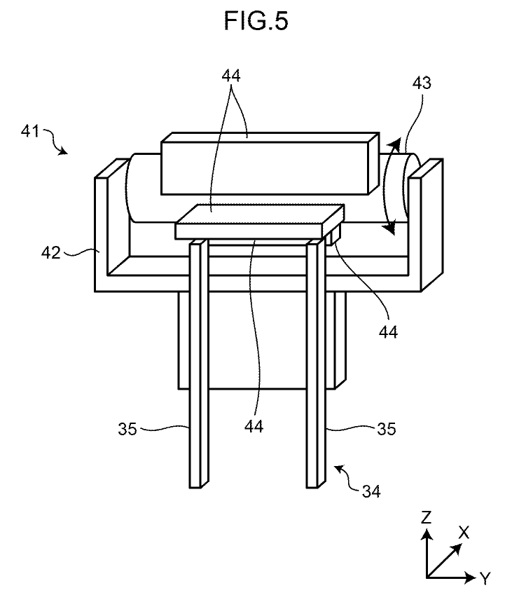

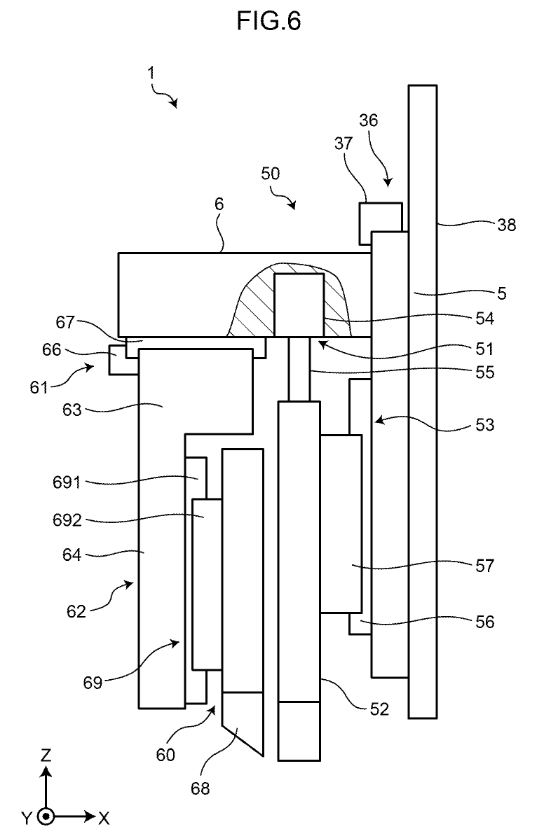

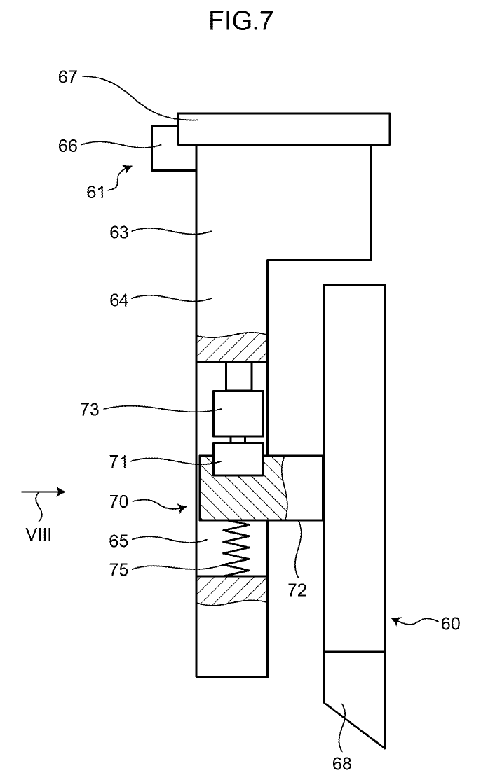

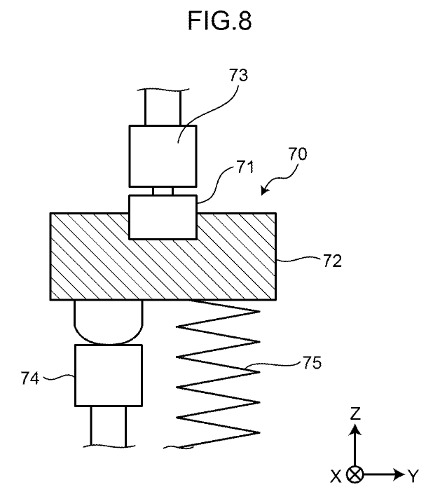

A braking device 1 that is a dividing device according to a first embodiment of the present invention is described with reference to the drawings. FIG. 1 is a perspective view schematically illustrating a configuration example of the braking device according to the first embodiment. FIG. 2 is a perspective view schematically illustrating a wafer unit including a wafer to be divided by the braking device illustrated in FIG. 1. FIG. 3 is a cross-sectional view schematically illustrating a main part in a state in which a division starting point is formed in the wafer illustrated in FIG. 2. FIG. 4 is a side view schematically illustrating a configuration of the braking device illustrated in FIG. 1 in a partial cross section. FIG. 5 is a perspective view schematically illustrating a configuration of a lower clamping unit of a clamping unit of the braking device illustrated in FIG. 1. FIG. 6 is a side view schematically illustrating a configuration of an upper clamping unit of the clamping unit of the braking device illustrated in FIG. 1 in a partial cross section. FIG. 7 is a side view schematically illustrating a pressing bar of the braking device illustrated in FIG. 1 in a partial cross section. FIG. 8 is a front view schematically illustrating a load measuring unit viewed from a direction of an arrow VIII illustrated in FIG. 7 in a partial cross section.

### Wafer Unit

The braking device 1 that is a dividing device illustrated in FIG. 1 according to the first embodiment is a device that divides a wafer 200 illustrated in FIG. 2 into individual chips 210. The wafer 200 to be divided by the braking device 1 illustrated in FIG. 1 is, for example, a disk-shaped semiconductor wafer having a base layer 201 made of silicon carbide (SiC) and a ductile material layer 212.

As illustrated in FIG. 2, in the wafer 200, a plurality of planned division lines 203 crossing each other are set on a front surface 202 of the base layer 201, and devices 204 (corresponding to chips) are formed in a region (corresponding to a chip region) to be sectioned by the planned division lines 203. That is, the base layer 201 includes a region where the devices 204 are formed on the front surface 202 side. As such, on the wafer 200, the plurality of planned division lines 203 parallel to one direction and the plurality of planned division lines 203 parallel to the other direction intersecting (in the first embodiment, orthogonal to) the one direction are set.

The device 204 is, for example, an integrated circuit (IC) or a large scale integration (LSI), a charge coupled device (CCD), or a memory (semiconductor storage device).

As illustrated in FIG. 2, the wafer 200 has division starting points 205 formed at least in the base layer 201 along the planned division lines 203. In the first embodiment, the division starting points 205 are grooves formed on the front surface 202 along the planned division lines 203. In first embodiment, for example, as illustrated in FIG. 3, the division starting point 205 is formed by cutting, by a cutting blade 220, the base layer 201 at the center in the width direction of the planned division line 203 from the front surface 202 side of the wafer 200 up to the center of the thickness of the base layer 201.

In the first embodiment, the division starting points 205 are the grooves described above but may be, in the present invention, modified layers formed along the planned division lines 203 inside the base layer 201. The modified layer means a region having density, a refractive index, mechanical strength, and other physical characteristics which are different from those of the surrounding region, and examples thereof include a molten processed region, a crack region, a dielectric breakdown region, a refractive index change region, and a region in which these regions are mixed. The modified layer has mechanical strength lower than that of other portions of the base layer 201. The modified layer is formed by irradiation with the laser beam with a wavelength having transparency to the wafer 200 along the planned division lines 203 under a condition the focal point is set inside the base layer 201.

As illustrated in FIG. 2, the ductile material layer 212 is formed on a back surface 206 side on the back side (corresponding to the opposite side) of the front surface 202 of the base layer 201 and is made of a ductile material (metal in the first embodiment). In the first embodiment, the ductile material layer 212 is made of gold with high ductility among metals and has a thickness of 2.5 μm. As such, in the first embodiment, the ductile material layer 212 is thicker than 1.0 μm that is a general thickness in the case of being made of gold. In the present invention, the ductile material layer 212 may have a thickness of 1.5 μm to 3.0 μm.

In the first embodiment, the wafer 200 is divided into the individual chips 210 along the planned division lines 203. Note that the chip 210 includes a part of the base layer 201, the device 204 formed on the front surface of the base layer 201, and the ductile material layer 212 on the back surface 206 side of the base layer 201. As such, in the first embodiment, the wafer 200 has the division starting points 205 formed along the planned division lines 203 that sections the chip region where the chips 210 are formed, and the ductile material layer 212 is divided for each chip 210.

In the first embodiment, as illustrated in FIG. 2, the wafer 200 configures a wafer unit 211 together with a disk-shaped sheet 207 and an annular frame 208. The disc-shaped sheet 207 is attached to the back surface 206 and has a larger diameter than the wafer 200. The frame 208 is attached to the outer periphery of the sheet 207 and has an inner diameter larger than the outer diameter of the wafer 200.

As described above, the wafer unit 211 includes the wafer 200, the sheet 207 on which the back surface 206 of the wafer 200 is adhered (fixed) to the central portion, and the frame 208. Note that in the present invention, the wafer unit 211 may not include the frame 208 as long as the wafer 200 and the sheet 207 are included.

In the first embodiment, in the wafer 200, a linear orientation flat 213 indicating the crystal structure of the base layer 201 is formed at the outer edge portion. The orientation flat 213 is parallel to one of the planned division lines 203 that intersect each other.

The sheet 207 is an adhesive tape including a base layer configured with a resin having non-adhesiveness and flexibility, and an adhesive layer laminated on the base layer and configured with a resin having adhesiveness and flexibility. The adhesive layer is attached to the wafer 200 and the frame 208. The sheet 207 has elasticity.

### Braking Device

Next, the braking device 1 that is a dividing device according to the first embodiment is described. The braking device 1 is a device that divides the wafer 200 along the planned division lines 203 to manufacture the chips 210. As illustrated in FIGS. 1 and 4, the braking device 1 includes a fixing unit 10, a detection unit 20, a clamping unit 40, a first pressing bar 60 (corresponding to the pressing bar), second pressing bars 80 (illustrated in FIG. 4), a control unit 100, a display unit 110, and an input unit (not illustrated).

The fixing unit 10 fixes the wafer unit 211 via the frame 208. The fixing unit 10 includes a moving frame 11 provided on a device main body 2 so as to be movable in the X-axis direction parallel to the horizontal direction by an X-axis moving unit 30, and a frame fixing member 12 provided on the moving frame 11.

The frame fixing member 12 is formed in an annular shape having inner and outer diameters equal to the inner and outer diameters of the frame 208. The upper surface of the frame fixing member 12 serves as a holding surface 13 on which the frame 208 is placed via the outer periphery of the sheet 207. The holding surface 13 is flat along the horizontal direction. In the first embodiment, in the frame fixing member 12, a suction hole connected to a suction source (not illustrated) is opened on the holding surface 13.

The fixing unit 10 sucks and fixes the frame 208 placed on the holding surface 13 by suction through the suction hole using the suction source. Note that in the present invention, when the frame 208 is configured with a magnetic material, the fixing unit 10 may be configured such that a magnet (permanent magnet or electromagnet) is arranged in the frame fixing member 12 to magnetically attract and fix the frame 208 placed on the holding surface 13. In the first embodiment, as illustrated in FIG. 4, the fixing unit 10 includes a frame clamp 14 that clamps and fixes the frame 208.

The fixing unit 10 is rotatable about its axis parallel to the Z-axis direction (also referred to as a vertical direction) by a rotary drive mechanism (not illustrated). In the present invention, when the wafer unit 211 does not include the frame 208, the fixing unit 10 may fix, via the sheet 207, the outer peripheral surplus region of the outer edge portion where the devices 204 of the wafer 200 are not formed.

The X-axis moving unit 30 is mounted on the device main body 2 and includes a known ball screw that is rotatably provided about its axis, a known motor that causes the ball screw to rotate about its axis to thereby move the moving frame 11 and the frame fixing member 12 in the X-axis direction, and known guide rails 31 that support the moving frame 11 to be movable in the X-axis direction.

The detection unit 20 detects the planned division line 203 of the wafer 200 of the wafer unit 211 to which the frame 208 has been fixed by the fixing unit 10. The detection unit 20 is mounted on a moving table 4 that is moved in the Y-axis direction parallel to the horizontal direction and orthogonal to the X-axis direction by a Y-axis moving unit 32. The Y-axis moving unit 32 is mounted on a gate-shaped frame 3 that is erected from the device main body 2 across the guide rails 31 of the X-axis moving unit 30. The detection unit 20 is mounted on the moving table 4 so as to be movably arranged in the Y-axis direction by the Y-axis moving unit 32.

The detection unit 20 includes an imaging camera 21 including an imaging element such as a charge coupled device (CCD) or a complementary MOS (CMOS) imaging element that images an object facing in the Z-axis direction parallel to the vertical direction with an objective lens. The detection unit 20 acquires an image captured by the imaging element and outputs the acquired image to the control unit 100. The detection unit 20 captures an image of the wafer 200 placed in an opening 209 of the frame 208 of the wafer unit 211 fixed by the fixing unit 10, detects the planned division lines 203 of the wafer 200, and acquires an image for performing alignment for aligning the planned division lines 203 of the wafer 200 with pressing bars 60 and 80, and the like.

The gate-shaped frame 3 and the moving table 4 each have a flat plate shape whose two surfaces are parallel to the Z-axis direction parallel to the vertical direction, and are overlapped in parallel with a gap. The Y-axis moving unit 32 is mounted on the gate-shaped frame 3 and includes a known ball screw that is rotatably provided about its axis, a known motor that causes the ball screw to rotate about its axis to thereby move the moving table 4 in the Y-axis direction, and known guide rails 33 that support the moving table 4 to be movable in the Y-axis direction.

The clamping unit 40 clamps, from above and below along the Z-axis direction, a region adjacent to the planned division line 203 along which the wafer 200 is to be divided. As illustrated in FIG. 4, the clamping unit 40 includes a lower clamping unit 41 and an upper clamping unit 50.

The lower clamping unit 41 is disposed below the fixing unit 10 and presses, from below, a region adjacent to the planned division line 203 of the wafer 200 placed in the opening 209 of the frame 208 of the wafer unit 211 fixed to the fixing unit 10. As illustrated in FIG. 5, the lower clamping unit 41 includes a bracket 42 provided to be movable up and down in the Z-axis direction by a Z-axis moving unit 34, a rotating body 43 rotatably supported by the bracket 42 about its axis, and a plurality of rectangular clamping members 44 (corresponding to clamping bars and clamper) having mutually different lengths protruding from the outer peripheral surface of the rotating body 43.

The rotating body 43 is arranged such that its axis is parallel to the Y-axis direction, and both ends thereof are rotatably supported by the bracket 42. The rotating body 43 is rotated about its axis by a rotation mechanism (not illustrated). Each of the rectangular clamping members 44 is formed in a rectangular plate shape having a linear shape in the Y-axis direction with a constant thickness and is formed to have various lengths with different lengths in the Y-axis direction. The length of the longest rectangular clamping member 44 among the plurality of rectangular clamping members 44 is the diameter of the wafer 200 (that is, the maximum length of the planned division line 203) + about 10 mm. In the rotating body 43, there are provided several types (for example, a total of four) of rectangular clamping members 44 having lengths shorter than the longest rectangular clamping member 44, and the lengths of the rectangular clamping members 44 are set so as not to collide with the frame 208 at the time of division along the planned division lines 203.

The protruding directions of the rectangular clamping members 44 are changed in accordance with the rotation of the rotating body 43. Among the rectangular clamping members 44, when the rectangular clamping member 44 arranged so as to protrude upward along the Z-axis direction from the rotating body 43 is lowered by the Z-axis moving unit 34, an upper end thereof is positioned below the sheet 207 attached to the wafer 200 placed in the opening 209 of the frame 208 fixed by the fixing unit 10, and when the rectangular clamping member is raised by the Z-axis moving unit 34, the upper end thereof is positioned above the wafer 200 placed in the opening 209 of the frame 208 fixed by the fixing unit 10. Among the rectangular clamping members 44, when the rectangular clamping member 44 arranged so as to protrude upward along the Z-axis direction from the rotating body 43 is raised by the Z-axis moving unit 34, the upper end thereof presses the devices 204 adjacent to the planned division line 203 of the wafer 200 upward from the back surface 206 side.

That is, in the lower clamping unit 41, the length of the rectangular clamping member 44 that protrudes upward can be selected by changing the direction (rotation) of the rotating body 43 about its axis, and the selected rectangular clamping member 44 presses the devices 204 positioned adjacent to the planned division line upward from the back surface 206 side.

Note that the Z-axis moving unit 34 includes a known ball screw provided rotatably about its axis, a known motor that causes the ball screw to rotate about the axis to thereby raise and lower the bracket 42 in the Z-axis direction, and known guide rails 35 that support the bracket 42 so as to be movable in the Z-axis direction.

In the first embodiment, the lower clamping unit 41 is moved in the X-axis direction by a horizontal movement mechanism 45 (illustrated in FIG. 4) together with the Z-axis moving unit 34. The horizontal movement mechanism 45 is mounted on the device main body 2 or the like.

The upper clamping unit 50 is arranged above the fixing unit 10 and clamps (sandwiches), between the upper clamping unit 50 and the lower clamping unit 41, the device 204 that corresponds to a region adjacent to the planned division line 203, along which the wafer 200 placed in the opening 209 of the frame 208 fixed by the fixing unit 10 is to be divided, and that is pressed from below by the lower clamping unit 41. The upper clamping unit 50 is mounted on a movable platform 5 and is disposed adjacent to the detection unit 20 in the Y-axis direction. The movable platform 5 is moved in the Z-axis direction by a lifting unit 36 mounted on the moving table 4.

The movable platform 5 is formed in a flat plate shape whose two surfaces are parallel to the Z-axis direction, and is stacked on the moving table 4 with a gap. A horizontal member 6 whose two surfaces are parallel to the horizontal direction is fixed to the movable platform 5.

The lifting unit 36 is mounted on the moving table 4 and includes a known ball screw that is rotatably provided about the axis, a known motor 37 that causes the ball screw to rotate about its axis to thereby raise and lower the movable platform 5 in the Z-axis direction, and known guide rails 38 that support the movable platform 5 to be movable in the Z-axis direction.

As illustrated in FIG. 6, the upper clamping unit 50 includes a cylinder unit 51, an upper clamping member 52 (corresponding to the clamping bar and the clamper), and a slide unit 53. The cylinder unit 51 includes: a cylinder 54 fixed to the horizontal member 6; and a rod 55, which is formed in a rod shape parallel to the Z-axis direction, is extendable from the cylinder 54, and whose lower end is lowered when extending from the cylinder 54.

The upper clamping member 52 is formed in a linear shape having a constant thickness in the Y-axis direction and a rectangular plate shape whose two surfaces are parallel to the Z-axis direction, and the length in the Y-axis direction is equal to the length of the longest planned division line 203 of the wafer 200. The lower end of the rod 55 of the cylinder unit 51 is fixed to the upper end of the upper clamping member 52, and the upper clamping member 52 is overlapped on the movable platform 5 with a gap. The upper clamping member 52 faces, in the Z-axis direction, the rectangular clamping member 44 protruding upward from the rotating body 43.

The slide unit 53 supports the upper clamping member 52 to be slidable in the Z-axis direction relative to the movable platform 5. The slide unit 53 includes a linear guide rail 56 fixed to the movable platform 5, which is one of the movable platform 5 and the upper clamping member 52, and being parallel to the Z-axis direction, and a slider 57 fixed to the upper clamping member 52, which is the other of the movable platform 5 and the upper clamping member 52, and supported on the guide rail 56 so as to be slidable in the longitudinal direction of the guide rail 56, that is, in the Z-axis direction.

The upper clamping member 52 is raised by the lifting unit 36 with the rod 55 being extended, whereby a lower end thereof is positioned above the wafer 200 placed in the opening 209 of the frame 208 of the wafer unit 211 fixed by the fixing unit 10, and when the upper clamping member is lowered by the lifting unit 36, the upper clamping member 52 clamps (sandwiches), between the upper clamping member 52 and the rectangular clamping member 44, a region which is adjacent to the planned division line 203 of the wafer 200 and whose lower end is pressed by the rectangular clamping member 44 arranged to protrude upward from the rotating body 43 along the Z-axis direction.

As such, the clamping members 44 and 52 of the clamping unit 40 correspond to a pair of clamping bars and a clamper, which clamp (sandwich) a first region of the wafer unit 211 from above and below the wafer unit 211. The first region is adjacent to the planned division line 203 and is on one side of the planned division line 203.

The first pressing bar 60 presses a second region of the wafer unit 211 along the planned division line 203. The second region is on the opposite side of the planned division line 203. As illustrated in FIG. 6, the first pressing bar 60 is installed on a pressing movable platform 62.

The pressing movable platform 62 has two surfaces parallel to the Z-axis direction. The pressing movable platform is integrally formed with a thick portion 63 on the upper end side and a thin portion 64 on the lower end side and is overlapped on the upper clamping member 52 with a gap. In the first embodiment, in the pressing movable platform 62, the front surfaces of the thick portion 63 and the thin portion 64 on the side away from the upper clamping member 52 are formed in the same plane, and a step between the thick portion 63 and the thin portion 64 is formed on the upper clamping member 52 side. In the first embodiment, the pressing movable platform 62 is provided with an opening 65 having a rectangular planar shape penetrating the thin portion 64. The pressing movable platform 62 is moved in the X-axis direction by a second X-axis moving unit 61.

The second X-axis moving unit 61 is attached to the horizontal member 6. The second X-axis moving unit 61 includes a known ball screw provided rotatably about its axis, a known motor 66 that causes the pressing movable platform 62 to move in the X-axis direction by rotating the ball screw about the axis, and known guide rails 67 that support the pressing movable platform 62 to be movable in the X-axis direction.

The first pressing bar 60 is formed in a linear shape in the Y-axis direction and a rectangular plate shape having two surfaces parallel to the Z-axis direction, and the length in the Y-axis direction is equal to the length of the longest planned division line 203 of the wafer 200. The first pressing bar 60 has, at the lower end portion thereof, a tapered portion 68 that gradually decreases in thickness as it goes downward. In the first embodiment, the tapered portion 68 has a front surface on the upper clamping member 52 side formed flat along the Z-axis direction, and the front surface on the side away from the upper clamping member 52 is inclined with respect to both the horizontal direction and the Z-axis direction in a direction gradually approaching the upper clamping member 52 as it goes downward.

The first pressing bar 60 is slidably supported with respect to the pressing movable platform 62 in the Z-axis direction by a pair of slide units 69. The slide units 69 are arranged with a gap in the Y-axis direction. The slide unit 69 includes: a linear guide rail 691 fixed to the pressing movable platform 62, which is one of the pressing movable platform 62 and the first pressing bar 60, and parallel to the Z-axis direction; and a slider 692 fixed to the first pressing bar 60, which is the other of the pressing movable platform 62 and the first pressing bar 60, and supported on a guide rail 691 so as to be slidable in the longitudinal direction of the guide rail 691, that is, in the Z-axis direction.

The first pressing bar 60 is raised by the lifting unit 36, whereby the lower end thereof is positioned above the wafer 200 placed in the opening 209 of the frame 208 fixed by the fixing unit 10, and when the first pressing bar 60 is lowered by the lifting unit 36, the first pressing bar 60 downward presses a region where the planned division line 203 is positioned between the clamping members 44 and 52.

The first pressing bar 60 is fixed to the pressing movable platform 62 by a load measuring unit 70 illustrated in FIG. 7. The load measuring unit 70 is disposed between the pair of slide units 69. As illustrated in FIGS. 7 and 8, the load measuring unit 70 includes a load meter 71 that measures a value (hereinafter, referred to as a load value) of a load that the first pressing bar 60 presses the wafer 200, a holding member 72, a support member 73, a spring 75, a support unit 74 (only illustrated in FIG. 8).

The load meter 71 measures a load value at which the first pressing bar 60 in the Z-axis direction presses the wafer 200 and is a known load cell in the first embodiment, but is not limited to the load cell. The load meter 71 outputs a load value, which is a measurement result, to the control unit 100. The load meter 71 is disposed in the opening 65 of the pressing movable platform 62.

The holding member 72 has one end portion fixed to the first pressing bar 60 and extends from the first pressing bar 60 toward the pressing movable platform 62 so that the other end portion thereof is disposed in the opening 65 of the pressing movable platform 62. The holding member 72 supports the lower end of the load meter 71 in the other end portion.

The support member 73 is disposed in the opening 65 of the pressing movable platform 62 and has an upper end fixed to an upper inner surface of the opening 65 and a lower end supporting an upper end of the load meter 71. The support unit 74 is disposed in the opening 65 of the pressing movable platform 62 and has the lower end fixed to the lower inner surface of the opening 65 and the upper end supporting the lower end portion of the holding member 72.

The spring 75 is disposed between the lower inner surface of the opening 65 and the other end portion of the holding member 72 and biases the first pressing bar 60 upward relatively to the pressing movable platform 62 via the other end portion of the holding member 72. In the first embodiment, the spring 75 urges the holding member 72 and the first pressing bar 60 upward with a force corresponding to the combined mass of the first pressing bar 60, the holding member 72, and the load meter 71. By the urging of the spring 75 with the above-described force, the combined mass of the first pressing bar 60, the holding member 72, and the load meter 71 is canceled, and the load meter 71 can measure a load value smaller than the combined mass of the first pressing bar 60, the holding member 72, and the load meter 71. As described above, the braking device 1 includes the load meter 71 that measures a load value at which the first pressing bar 60 presses the wafer 200.

The second pressing bar 80 is a component different from the first pressing bar 60 and presses the second region of the wafer unit from the back surface 206 side opposite to the front surface 202 side along the planned division line 203. As illustrated in FIG. 4, the plurality of second pressing bars 80 is provided on the outer peripheral surface of a rotating body 81 rotatably supported about its axis disposed below the fixing unit 10.

The rotating body 81 has an axis disposed parallel to the Y-axis direction and is rotated about the axis by a rotation mechanism (not illustrated). The second pressing bars 80 each extend linearly in the Y-axis direction and are formed to have various different lengths in the Y-axis direction. The length of the longest second pressing bar 80 among the second pressing bars 80 is the diameter of the wafer 200 (that is, the maximum length of the planned division line 203) + about 10 mm.

The second pressing bars 80 are provided with several types (for example, a total of four) of the second pressing bars 80 shorter than the longest second pressing bar 80, and the lengths thereof are set so as not to collide with the frame 208 at the time of division along the planned division line 203. The protruding directions of the second pressing bars 80 are changed in accordance with the rotation of the rotating body 81.

When the second pressing bar 80 is disposed so as to protrude upward from the rotating body 81 along the Z-axis direction, a tapered portion 82 having the thickness gradually decreases toward the upper side is formed in the upper end portion of the second pressing bar 80. In the first embodiment, the tapered portion 82 has a surface on the rectangular clamping member 44 side formed flat along the Z-axis direction, and the front surface on the side away from the rectangular clamping member 44 is gradually inclined with respect to both the horizontal direction and the Z-axis direction in a direction approaching the rectangular clamping member 44 as it goes downward.

As illustrated in FIG. 4, the rotating body 81 provided with the second pressing bars 80 on the outer peripheral surface is moved in the X-axis direction by a gap adjustment mechanism 83, and the gap adjustment mechanism 83 is raised and lowered in the Z-axis direction by a lifting mechanism 84. The distance between the second pressing bar 80 and the rectangular clamping member 44 is adjusted by moving the rotating body 81 in the X-axis direction by the gap adjustment mechanism 83.

When the second pressing bar 80 is lowered by the lifting mechanism 84, the upper end thereof is positioned below the sheet 207 attached to the wafer 200 placed in the opening 209 of the frame 208 fixed by the fixing unit 10, and when the second pressing bar 80 is raised by the lifting mechanism 84, the upper end thereof is positioned above the wafer 200 placed in the opening 209 of the frame 208 fixed by the fixing unit 10. Among the plurality of second pressing bars 80, when the second pressing bar 80 arranged so as to protrude upward along the Z-axis direction from the rotating body 43 is raised by the lifting mechanism 84, the upper end thereof presses the region adjacent to the planned division line 203 upward from the back surface 206 side.

That is, in the second pressing bar 80, the length of the second pressing bar 80 that protrudes upward can be selected by changing the direction (rotation) of the rotating body 43 about its axis, and the selected second pressing bar 80 presses the region adjacent to the planned division line 203 upward from the back surface 206 side. The lifting mechanism 84 is mounted on the device main body 2 or the like.

Note that in the present invention, the lifting mechanism 84 is connected on the guide rails 31 of the X-axis moving unit 30, and guide rails of the gap adjustment mechanism 83 can be replaced with the guide rails 31 of the X-axis moving unit 30. Therefore, a part of the gap adjustment mechanism 83 of the second pressing bar 80 may also serve as the X-axis moving unit 30.

The control unit 100 controls the above-described components of the braking device 1 to cause the braking device 1 to perform a division operation of dividing the wafer 200 along each of the planned division lines 203. The control unit 100 is a computer including an arithmetic processing device with a microprocessor such as a central processing unit (CPU), a storage device with a memory such as a read only memory (ROM) or a random access memory (RAM), and an input/output interface device.

The arithmetic processing device of the control unit 100 performs arithmetic processing according to a computer program stored in the storage device and outputs a control signal for controlling the braking device 1 to each of the above-described units of the braking device 1 via the input/output interface device. The control unit 100 determines a division result for each planned division line 203 based on the load value measured by the load meter 71 and stores the division results in one-to-one association with the planned division lines 203.

The display unit 110 is connected to the control unit 100 and includes a display screen 111 that displays various types of information. The input unit is used when the operator inputs information and the like to the control unit 100 of the braking device 1. The input unit is connected to the control unit 100 and outputs the input information to the control unit 100. The input unit includes a touch panel superimposed on the display screen 111 of the display unit 110.

### Method of Manufacturing a chip

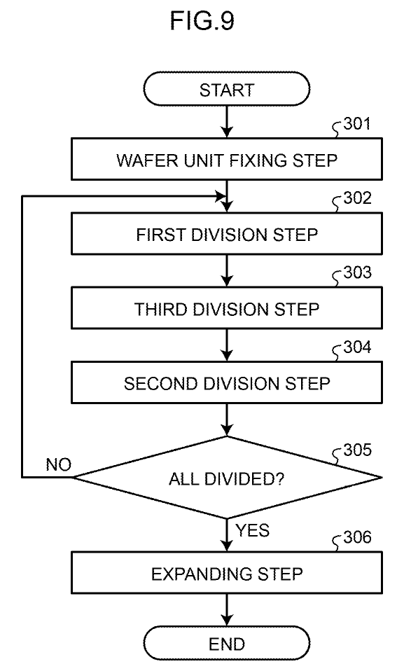

Next, a method of manufacturing chips according to the first embodiment is described. FIG. 9 is a flowchart illustrating a flow of the method of manufacturing chips according to the first embodiment. The method of manufacturing chips according to the first embodiment is a method of manufacturing the chips 210 by dividing the wafer 200 along the planned division lines 203. In the first embodiment, as illustrated in FIG. 9, the method of manufacturing chips includes a wafer unit fixing step 301, a first division step 302, a third division step 303, a second division step 304, and an expanding step 306. Note that in the first embodiment, the wafer unit fixing step 301, the first division step 302, the third division step 303, and the second division step 304 are performed by the braking device 1.

### Wafer Unit Fixing Step

The wafer unit fixing step 301 is a step of fixing the sheet 207 of the wafer unit 211 having the above-described configuration. In the first embodiment, in the wafer unit fixing step 301, in the braking device 1, first, an operator or the like operates the input unit to input a division condition, and the control unit 100 receives and registers the division condition. When the control unit 100 receives an instruction to start the division operation from the operator or the like, the braking device 1 starts the division operation, that is, the wafer unit fixing step 301 in the first embodiment.

In the first embodiment, in the wafer unit fixing step 301, the control unit 100 of the braking device 1 controls the Z-axis moving unit 34 to lower the lower clamping unit 41, controls the cylinder unit 51 of the upper clamping unit 50 to retract the rod 55, and controls the lifting unit 36 to raise the upper clamping unit 50 and the first pressing bar 60. In the first embodiment, in the wafer unit fixing step 301, the control unit 100 of the braking device 1 controls the lifting mechanism 84 to lower the rotating body 81 and the second pressing bar 80.

In the first embodiment, in the wafer unit fixing step 301, the control unit 100 of the braking device 1 controls the X-axis moving unit 30 to retract the fixing unit 10 from between the clamping units 41 and 50. In the first embodiment, in the wafer unit fixing step 301, the frame 208 of the wafer unit 211, in which the wafer 200 is placed in the opening 209, is placed on the holding surface 13 of the fixing unit 10 in the braking device 1. In the first embodiment, in the wafer unit fixing step 301, in the braking device 1, the control unit 100 operates the suction source, and the frame clamp 14 fixes the frame 208 to the holding surface 13 of the fixing unit 10 to fix the sheet 207 of the wafer unit 211 to the fixing unit 10.

### First Division Step

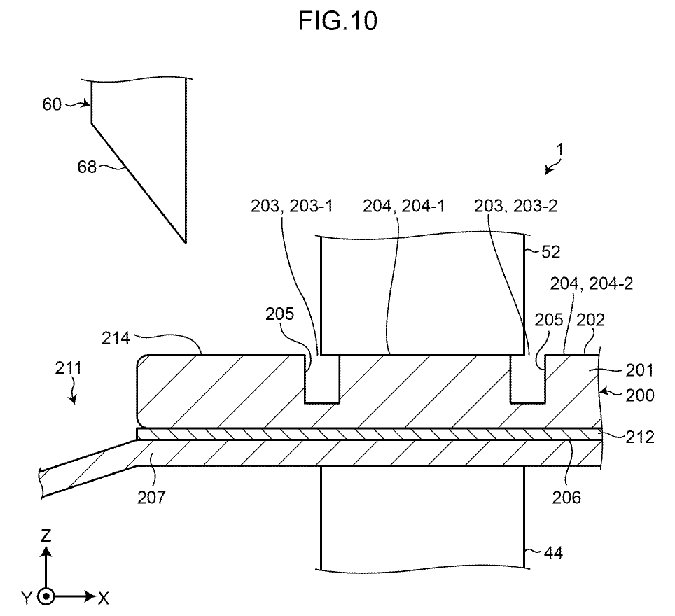

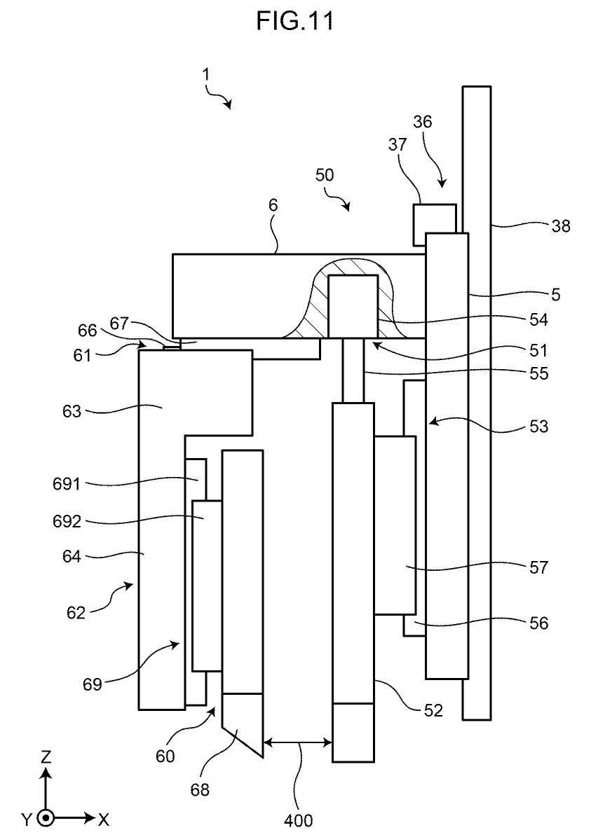

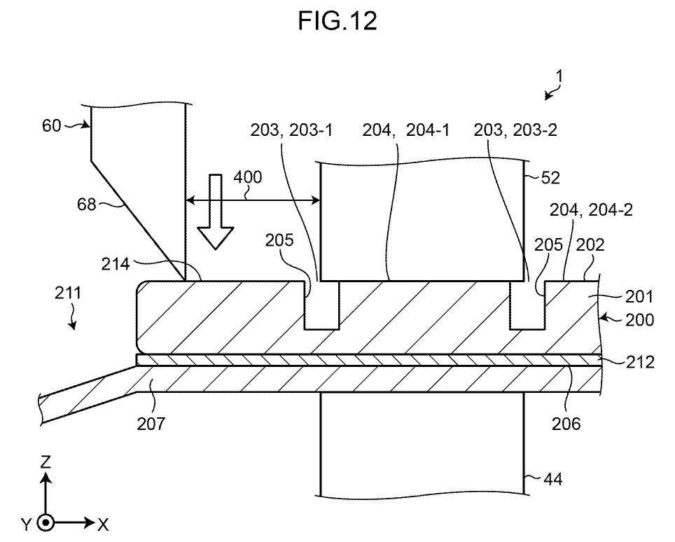

FIG. 10 is a diagram schematically illustrating a main part in a state where the wafer is clamped by the clamping members in the first division step of the method of manufacturing chips illustrated in FIG. 9 in a partial cross section. FIG. 11 is a side view schematically illustrating, in a partial cross section, the configuration of the upper clamping unit in a state where a distance between the first pressing bar and the upper clamping member is adjusted in the first division step of the method of manufacturing chips illustrated in FIG. 9. FIG. 12 is a diagram schematically illustrating the main part in a state where the first pressing bar presses the wafer in the first division step of the method of manufacturing a chip illustrated in FIG. 9 in a partial cross section.

The first division step 302 is a step of pressing, while clamping the first region of the wafer unit 211 by the clamping members 44 and 52 along a first planned division line 203-1 of the planned division lines 203, the second region of the wafer unit 211 along the first planned division line 203-1 from a back surface 206 side of the wafer or from a front surface 202 side opposite to the back surface 206 side. The first region is on one side of the first planned division line 203-1, and the second region is on the opposite side of the first planned division line 203-1. In the first embodiment, in the first division step 302, the braking device 1 captures an image of the front surface 202 of the wafer 200 with the imaging camera 21 of the detection unit 20 in a state where the control unit 100 controls the X-axis moving unit 30 and the Y-axis moving unit 32 to position the detection unit 20 above the wafer 200 of the wafer unit 211.

In the first embodiment, in the first division step 302, the braking device 1 detects the planned division lines 203 based on an image obtained by the control unit 100 capturing an image with the imaging camera 21 of the detection unit 20. Note that, in the first embodiment, capturing an image of the front surface 202 of the wafer 200 with the imaging camera 21 may be performed at a predetermined timing, such as each time the division for one planned division line 203 is performed or each time the division for five planned division lines 203 is performed.

In the first embodiment, in the first division step 302, the control unit 100 of the braking device 1 controls the rotary drive mechanism of the fixing unit 10 to position, to be parallel to the Y-axis direction, the planned division line 203 parallel to one direction of the wafer 200 of the wafer unit 211 to which the frame 208 is fixed by the fixing unit 10. In the first embodiment, in the first division step 302, the control unit 100 of the braking device 1 controls the rotation mechanism so that the rectangular clamping member 44 having a length corresponding to the planned division line 203-1 (corresponds to the first planned division line) along which the wafer is to be first divided is arranged so as to protrude upward from the rotating body 43. Note that the method of manufacturing a chip according to the first embodiment is described on the assumption that, the wafer is divided along the plurality of planned division lines 203 in order from the planned division line 203-1 positioned at one end to the planned division line 203 positioned at the other end, and in FIG. 10, the wafer is first divided along the planned division line (the first planned division line) 203-1 positioned at one extreme end.

In the first embodiment, in the first division step 302, the braking device 1 controls the X-axis moving unit 30 and the Y-axis moving unit 32 based on the position of the planned division line 203 which is detected by the control unit 100 capturing an image with the imaging camera 21 of the detection unit 20, positions the lower end of the upper clamping member 52 above the device 204-1 (i.e., the device 204 close to the center of the wafer 200 in the first embodiment), and positions the upper end of the rectangular clamping member 44 below the device 204-1. The device 204-1 corresponds to the first region of the wafer unit 211, which is adjacent to the planned division line 203-1 and positions on one side (but closer to the other side) of the planned division line 203-1.

In the first embodiment, in the first division step 302, the braking device 1 positions the first pressing bar 60 above a region 214, and positions the second pressing bar 80 below the region 214. The region 214 is the second region of the wafer unit 211, which is adjacent to the planned division line 203-1 and positions on the opposite side of the planned division line 203-1. In the first embodiment, the region 214 is a region where no device 204 is formed on the wafer 200 and is located closer to (but away from the edge of the wafer 200) the outer periphery than the device 204.

In the first embodiment, in the first division step 302, the control unit 100 of the braking device 1 controls the Z-axis moving unit 34 to raise the rotating body 43 and the rectangular clamping member 44, and presses the device 204-1, which corresponds to the first region of the wafer unit 211, upward through the sheet 207. Then, the wafer 200 is raised, and as illustrated in FIG. 10, the device 204-1 abuts on the lower end of the upper clamping member 52 and is clamped by the clamping members 44 and 52.

Note that, in the present invention, in the first division step 302, the upper clamping member 52 of the braking device 1 may be lowered after the rotating body 43 and the rectangular clamping member 44 are raised, or alternatively, the upper clamping member 52 may be lowered simultaneously with the rise of the rotating body 43 and the rectangular clamping member 44 to clamp the wafer 200. In the present invention, in the first division step 302, the wafer 200 may be clamped by positioning the upper clamping member 52 and the rectangular clamping member 44 aiming at a position where the wafer 200 is not raised nor lowered. In this case, there is an advantage that an unnecessary load is not applied to the wafer 200.

In this manner, in the first embodiment, in the first division step 302, the braking device 1 clamps the device 204-1, which corresponds to the first region of the wafer unit 211, between the clamping members 44 and 52 from the front surface 202 and the back surface 206 sides via the sheet 207.

In the first embodiment, in the first division step 302, the control unit 100 of the braking device 1 controls the second X-axis moving unit 61 to adjust the position of the first pressing bar 60 in the X-axis direction so that a distance 400 between the lower end of the upper clamping member 52 and the lower end of the first pressing bar 60 in the X-axis direction becomes 60% to 85% of the width of the chip 210 included in the division condition, as illustrated in FIG. 11. Note that in the present invention, the position of the first pressing bar 60 in the X-axis direction may be adjusted so that the distance 400 between the lower end of the upper clamping member 52 and the lower end of the first pressing bar 60 in the X-axis direction is 60% to 95% (that is, more than 50% and less than 100%) of the width of the chip 210. In the first embodiment, the width of the chip 210 is 5 mm, and the distance 400 is 3 mm.

In the first embodiment, in the first division step 302, the control unit 100 of the braking device 1 controls the lifting unit 36 based on the division condition to lower the movable platform 5 of the upper clamping unit 50 and the first pressing bar 60 with the wafer 200 being clamped by the clamping members 44 and 52. Thus, since the upper clamping member 52 clamps, via the sheet 207 with the rectangular clamping member 44, the device 204-1 corresponding to the first region of the wafer unit 211, the rod 55 of the cylinder unit 51 is retracted without lowering the upper clamping member 52, and the upper clamping member 52 rises relatively to the movable platform 5 by the slide unit 53.

When the movable platform 5 of the upper clamping unit 50 and the first pressing bar 60 are lowered, as illustrated in FIG. 12, the lower end of the first pressing bar 60 abuts on the region 214, which is the second region of the wafer unit 211. The first pressing bar 60 is further lowered, the lower end of the first pressing bar 60

is positioned below the lower end of the upper clamping member 52, and the first pressing bar 60 presses the region 214 from the front surface 202 side to divide the base layer 201 along the planned division line 203-1 between the clamping members 44 and 52 and the first pressing bar 60.

In the first embodiment, in the first division step 302, since the distance 400 between the lower end of the upper clamping member 52 and the lower end of the first pressing bar 60 in the X-axis direction is 60% to 85% of the width of the chip 210, the ductile material layer 212 is elastically deformed and curved by applying the bending stress, centered on the back surface 206 side of the planned division line 203-1. In the first embodiment, in the first division step 302, the control unit 100 of the braking device 1 controls the lifting unit 36 based on the division condition to lower the movable platform 5 of the upper clamping unit 50 and the first pressing bar 60 and then raise the movable platform 5 and the first pressing bar 60 again. Thus, the ductile material layer 212 and the region 214 return to their positions prior to the lowering of the first pressing bar 60.

In the first embodiment, in the first division step 302, the braking device 1 sets the lowering speed of the first pressing bar 60 to 2 mm/s and lowers the first pressing bar 60 so that the lower end of the first pressing bar 60 goes to 0.23 mm below the front surface 202 of the wafer 200.

### Third Division Step

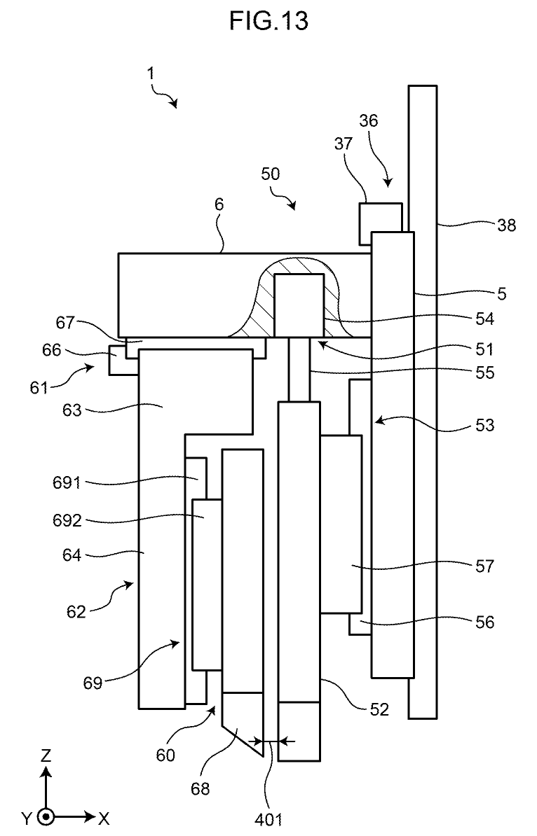

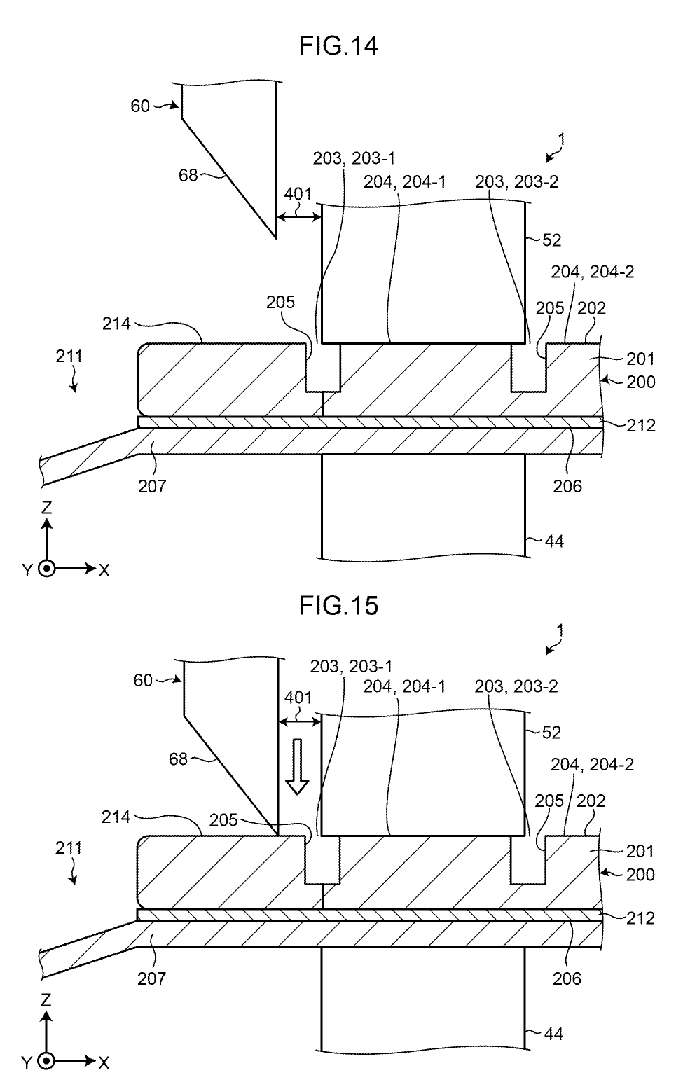

FIG. 13 is a side view schematically illustrating, in a partial cross section, the configuration of the upper clamping unit in a state where the first pressing bar is brought close to the upper clamping member in the third division step of the method of manufacturing a chip illustrated in FIG. 9. FIG. 14 is a diagram schematically illustrating, in a partial cross section, the main part in a state where the first pressing bar is brought close to the upper clamping member in the third division step of the method of manufacturing a chip illustrated in FIG. 9. FIG. 15 is a diagram schematically illustrating, in a partial cross section, the main part in a state where the first pressing bar is lowered in the third division step of the method of manufacturing a chip illustrated in FIG. 9. The third division step 303 is performed after the first division step 302 and before the second division step 304. The third division step 303 is a step of pressing the region 214, which corresponds to the second region of the wafer unit, at a position closer to the planned division line 203-1 than a position pressed in the first division step, from the back surface 206 side or from the front surface 202 side that is the same as in the first division step along the planned division line 203-1, while clamping the device 204-1, which corresponds to the first region of the wafer unit, by the clamping members 44 and 52 along the planned division line 203-1.

In the first embodiment, in the third division step 303, the control unit 100 of the braking device 1 controls the second X-axis moving unit 61 to adjust the position of the first pressing bar 60 in the X-axis direction so that a distance 401 between the lower end of the upper clamping member 52 and the lower end of the first pressing bar 60 in the X-axis direction becomes 10% to 20% (that is, more than 0% and less than 50%) of the width of the chip 210 included in the division condition, as illustrated in FIGS. 13 and 14.

In this manner, in the first embodiment, in the third division step 303, the gap between the position pressed by the first pressing bar 60 of the wafer 200 and the planned division line 203-1, that is, the distance 401 (illustrated in FIGS. 13 and 14) between the lower end of the upper clamping member 52 and the lower end of the first pressing bar 60 in the X-axis direction exceeds 0 mm, and is a half or less of the gap between the position pressed by the first pressing bar 60 of the wafer 200 and the planned division line 203-1 in the first division step 302, that is, the distance 400 (illustrated in FIGS. 11 and 12) between the lower end of the upper clamping member 52 and the lower end of the first pressing bar 60 in the X-axis direction. Note that in the first embodiment, the distance 401 is 0.5 mm.

In the first embodiment, in the third division step 303, the control unit 100 of the braking device 1 controls the lifting unit 36 based on the division condition to lower the movable platform 5 of the upper clamping unit 50 and the first pressing bar 60 with the wafer 200 being clamped by the clamping members 44 and 52. In the same manner as in the first division step 302, as illustrated in FIG. 15, the lower end of the first pressing bar 60 abuts on the region 214, which is the second region of the wafer unit 211.

In the first embodiment, in the third division step 303, the distance 401 between the lower end of the upper clamping member 52 and the lower end of the first pressing bar 60 in the X-axis direction is 10% to 20% of the width of the chip 210. Therefore, when the first pressing bar 60 is further lowered, the lower end of the first pressing bar 60 presses the region 214 downward from the front surface 202 side, and a shear stress is applied to the ductile material layer 212. However, since the ductile material layer 212 is made of a ductile material, the ductile material layer 212 is elastically deformed and curved, centered on the back surface 206 side of the planned division line 203-1.

In the third division step 303, in the braking device 1, the control unit controls the lifting unit 36 based on the division condition to lower the movable platform 5 of the upper clamping unit 50 and the first pressing bar 60 and then raise the movable platform 5 and the first pressing bar 60 again. Note that in the first embodiment, in the third division step 303, the braking device 1 sets the lowering speed of the first pressing bar 60 to 2 mm/s and lowers the first pressing bar 60 so that the lower end of the first pressing bar 60 goes to 0.23 mm below the front surface 202 of the wafer 200.

### Second Division Step

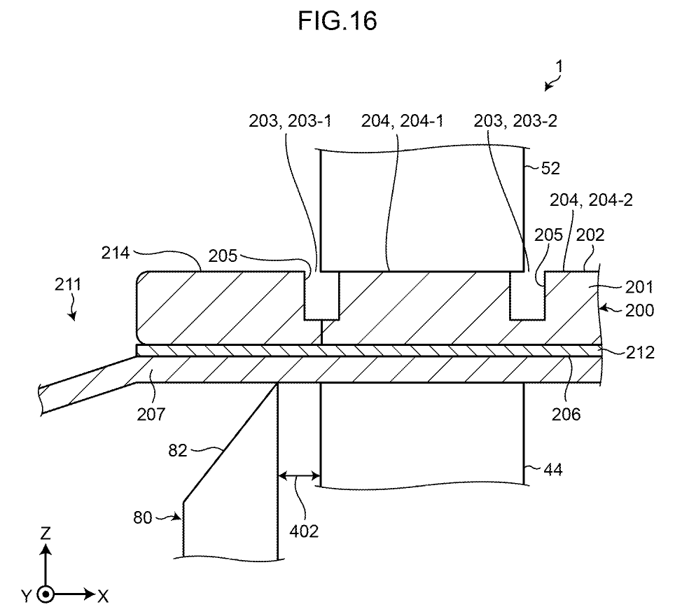

FIG. 16 is a diagram schematically illustrating a main part of the second division step of the method of manufacturing a chip illustrated in FIG. 9 in a partial cross section. The second division step 304 is performed after the first division step 302. The second division step is a step of pressing the region 214, which is the second region of the wafer unit, along the planned division line 203-1 from the back surface 206 side or from the front surface 202 side that is different from that in the first division step, while clamping the device 204-1, which corresponds to the first region of the wafer unit 211, by the clamping members 44 and 52 along the first planned division line.

In the first embodiment, in the second division step 304, the control unit 100 of the braking device 1 controls the rotation mechanism so that the second pressing bar 80 having a length corresponding to the planned division line 203-1 is arranged to protrude upward from the rotating body 81. In the first embodiment, in the second division step 304, the control unit 100 of the braking device 1 controls the gap adjustment mechanism 83 to adjust the position of the second pressing bar 80 in the X-axis direction so that a distance 402 (illustrated in FIG. 16) between the upper end of the rectangular clamping member 44 protruding upward and the upper end of the second pressing bar 80 in the X-axis direction becomes 10% to 20% (that is, more than 0% and less than 50%) of the width of the chip 210 included in the division condition.

As such, in the first embodiment, in the second division step 304, the gap between the position pressed by the second pressing bar 80 of the wafer 200 and the planned division line 203-1, that is, the distance 402 (illustrated in FIG. 16) of the upper end of the rectangular clamping member 44 protruding upward and the upper end of the second pressing bar 80 in the X-axis direction exceeds 0 mm, and is a half or less of the interval between the position pressed by the first pressing bar 60 of the wafer 200 and the planned division line 203-1 in the first division step 302, that is, the distance 400 (illustrated in FIGS. 11 and 12) between the lower end of the upper clamping member 52 and the lower end of the first pressing bar 60 in the X-axis direction. Note that in the first embodiment, the distance 402 is equal to the distance 401 between the lower end of the upper clamping member 52 and the lower end of the first pressing bar 60 in the X-axis direction in the third division step 303 and is 0.5 mm.

In the first embodiment, in the second division step 304, the control unit 100 of the braking device 1 controls the lifting mechanism 84 based on the division condition to raise the second pressing bar 80 protruding upward together with the rotating body 81 with the wafer 200 being clamped by the clamping members 44 and 52. Thus, as illustrated in FIG. 16, the upper end of the second pressing bar 80 abuts on the back surface 206 side of the region 214, which is the second region of the wafer unit 211.

In the first embodiment, in the second division step 304, the distance 401 between the lower end of the upper clamping member 52 and the lower end of the first pressing bar 60 in the X-axis direction is 10% to 20% of the width of the chip 210. Therefore, when the second pressing bar 80 is further raised, the upper end of the second pressing bar 80 presses the region 214 upward from the back surface 206 side, a shear stress is applied to the ductile material layer 212, and the ductile material layer 212 is divided along the planned division line 203-1 so that the division is performed along the planned division line 203-1.

In the second division step 304, the control unit 100 of the braking device 1 controls the lifting mechanism 84 based on the division condition to raise the rotating body 81 and the second pressing bar 80 and then lower the rotating body 81 and the second pressing bar 80 again. In the first embodiment, in the second division step 304, the braking device 1 sets the upward speed of the second pressing bar 80 to 2 mm/s and raises the second pressing bar 80 so that the upper end of the second pressing bar 80 goes to 0.23 mm above the lower surface of the sheet 207 attached to the back surface 206 of the wafer 200.

In the first embodiment, in the first division step 302 and the third division step 303, the control unit 100 determines a division result of the planned division line 203-1 based on the load value measured by the load meter 71 and stores the determined division result in association with the planned division line 203-1.

In the method of manufacturing a chip according to the first embodiment, the control unit 100 of the braking device 1 determines whether the divisions have been performed for all the planned division lines 203 of the wafer 200 (Step 305). In the method of manufacturing a chip according to the first embodiment, when determining that the divisions have not been performed for all the planned division lines 203 of the wafer 200 (Step 305: No), the control unit 100 of the braking device 1 determines whether the divisions have been performed for all the planned division lines 203 parallel to one direction. In the method of manufacturing a chip according to the first embodiment, when it is determined that the divisions have not been performed for all the planned division lines 203 parallel to one direction, the flow returns to the first division step 302.

In the returned first division step 302, the braking device 1 arranges the rectangular clamping member 44 having a length corresponding to a planned division line 203-2 along which the division has not yet performed (illustrated in FIG. 10 etc.) adjacent to the planned division line 203-1 along which the division has been formed, to protrude upward from the rotating body 43. In the returned first division step 302, the braking device 1 clamps, with clamping members 44 and 52, a device 204-2 (illustrated in FIG. 10 etc.), which corresponds to the first region of the wafer unit 211 positioning on one side of the planned division line 203-2 along which the division has not yet performed. Thereafter, in the first division step 302 and the third division step 303, the first pressing bar 60 etc. is lowered to press the device 204-1, which corresponds to the second region of the wafer unit 211 positioning on the opposite side of the planned division line 203-2, whereby the base layer 201 is divided along the planned division line 203-2. In the second division step 304, the second pressing bar 80 etc. is raised to press the device 204-1, whereby the ductile material layer 212 is divided along the planned division line 203-2.

In this manner, in the method of manufacturing a chip according to the first embodiment, the first division step 302, the third division step 303, and the second division step 304 are repeated to sequentially perform the division along the plurality of planned division lines 203 in an order from the planned division line 203 positioned at one end toward the planned division line 203 positioned at the other end and perform the divisions along all the plurality of planned division lines 203 parallel to one direction.

In the method of manufacturing a chip according to the first embodiment, when the control unit 100 of the braking device 1 determines that the divisions have been performed along all the planned division lines 203 parallel to one direction, the control unit 100 causes the fixing unit 10 to rotate by 90 degrees about its axis by the rotary drive mechanism, and then the flow returns to the first division step 302. In the method of manufacturing a chip according to the first embodiment, the control unit 100 of the braking device 1 repeatedly performs the first division step 302, the third division step 303, and the second division step 304, and the divisions are performed along all the planned division lines 203 parallel to the other direction. When determining that the divisions have been performed along all the planned division lines 203 (Step 305: Yes), the braking device 1 ends the dividing operation.

### Expanding Step

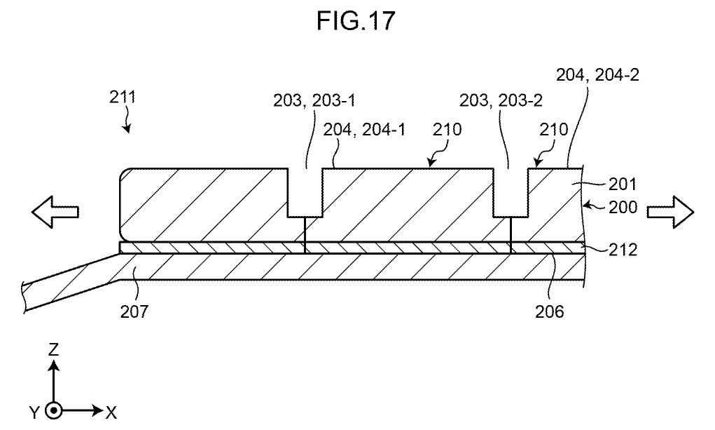

FIG. 17 is a diagram schematically illustrating a main part of an expanding step of the method of manufacturing a chip illustrated in FIG. 9 in a partial cross section. The expanding step 306 is a step of expanding the sheet 207 of the wafer unit 211 after the second division step 304. In the first embodiment, in the expanding step 306, the wafer unit 211 that has been divided along all the planned division lines 203 through the division steps 302, 303, and 304 is conveyed to a known expanding device (not illustrated). In the first embodiment, in the expanding step 306, the expanding device expands the sheet 207 of the wafer unit 211 as illustrated in FIG. 17. Thereafter, the divided chips 210 are picked up from the sheet 207.

In the method of manufacturing a chip and the braking device 1 according to the first embodiment described above, pressing is performed from the front surface 202 side along the planned division line 203 in the first division step 302, and pressing is performed from the back surface 206 side along the planned division line 203 in the second division step 304. Therefore, the ductile material layer 212 is curved so that the planned division line 203 is recessed toward both the ductile material layer 212 side and the base layer 201 side.

For this reason, in the method of manufacturing a chip and the braking device 1 according to the first embodiment, the ductile material layer 212 can be divided along the planned division line 203 and generation of burrs after the division can be suppressed.

As a result, the method of manufacturing a chip and the braking device 1 according to the first embodiment provides an advantageous effect of being able to divide the ductile material layer 212 without impairing the quality.

Further, in the method of manufacturing a chip and the braking device 1 according to the first embodiment, in addition to the first division step 302 and the second division step 304, in the third division step 303, pressing is performed from the front surface 202 side along the planned division line 203, the distance 401 of the third division step 303 is set to be less than 50% of the width of the chip 210, and the distance 400 of the first division step 302 is set to be an interval exceeding 50% of the width of the chip 210. As a result, in the method of manufacturing a chip and the braking device 1 according to the first embodiment, the bending stress is applied to the wafer 200 in the first division step 302, and the shear stress is applied to the wafer 200 in the third division step 303 and the second division step 304. This makes it possible to divide the ductile material layer 212 along the planned division line 203.

### Second Embodiment

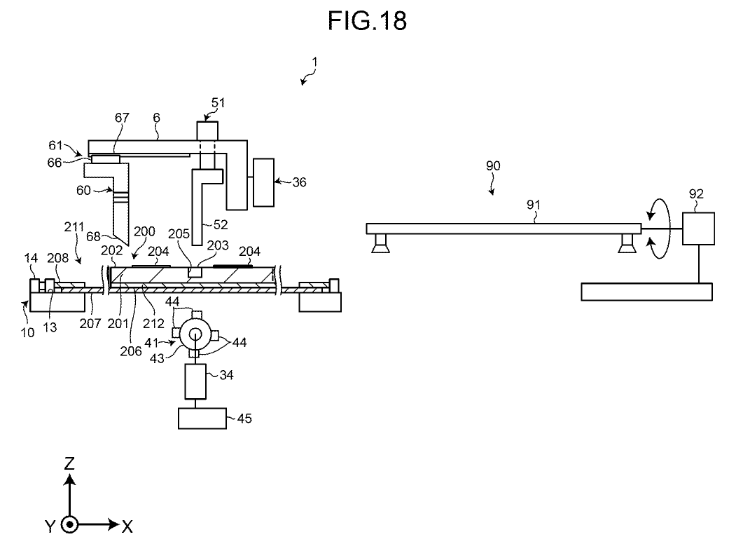

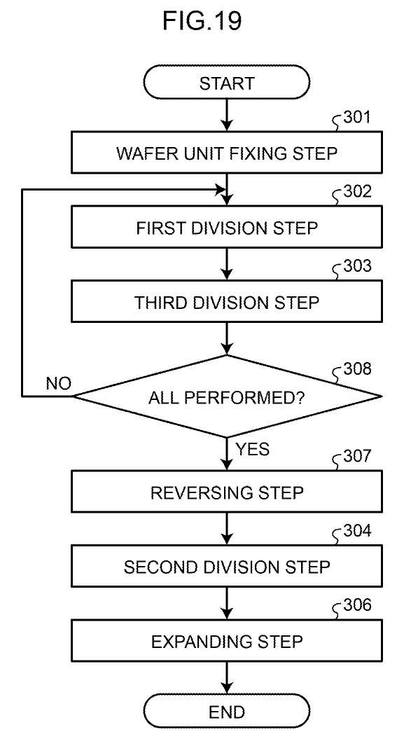

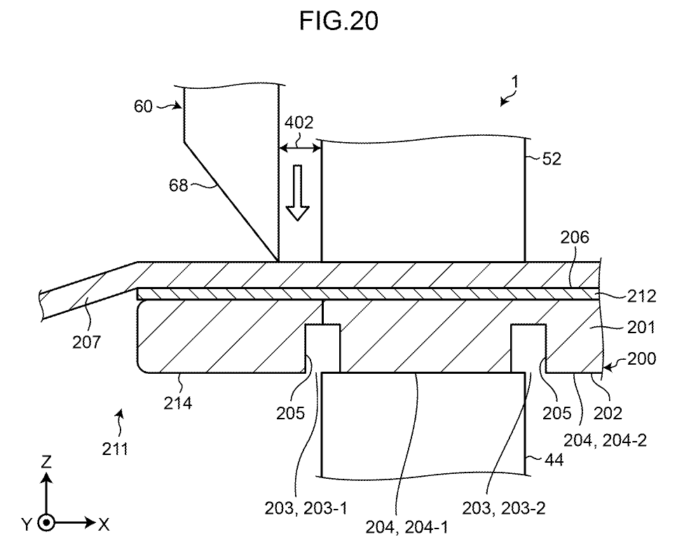

A braking device 1 that is a dividing device and a method of manufacturing a chip according to a second embodiment are described with reference to the drawings. FIG. 18 is a diagram schematically illustrating a configuration example of the braking device according to the second embodiment. FIG. 19 is a flowchart illustrating a flow of the method of manufacturing a chip according to the second embodiment. FIG. 20 is a diagram schematically illustrating a main part of the second division step of the method of manufacturing a chip illustrated in FIG. 19 in a partial cross section. Note that in FIGS. 18, 19, and 20, the same parts as those in the first embodiment are denoted by the same reference numerals, and description thereof is omitted.

As illustrated in FIG. 18, the braking device 1 that is a dividing device according to the second embodiment does not include the second pressing bar 80 but includes a reversing unit 90. The reversing unit 90 reverses the wafer unit 211. The reversing unit 90 includes a suction holding unit 91 that sucks and holds the frame 208 of the wafer unit 211, and a rotation unit 92 that rotates the suction holding unit 91 about its axis parallel to the horizontal direction. In the reversing unit 90, after the suction holding unit 91 sucks and holds the frame 208 of the wafer unit 211 on the holding surface 13 of the fixing unit 10, and the rotation unit 92 reverses the suction holding unit 91 about its axis, the frame 208 of the wafer unit 211 sucked and held by the suction holding unit 91 is placed on the holding surface 13 of the fixing unit 10 and the front and back of the wafer unit 211 are reversed.

As illustrated in FIG. 19, the method of manufacturing a chip according to the second embodiment includes a reversing step 307, in addition to the wafer unit fixing step 301, the first division step 302, the third division step 303, the second division step 304, and the expanding step 306. In the method of manufacturing a chip according to the second embodiment, the first division step 302 and the third division step 303 are performed for all the planned division lines 203.

In the method of manufacturing a chip according to the second embodiment, after the third division step 303, when it is determined that the first division step 302 and the third division step 303 have been performed along all the planned division lines 203 (Step 308: Yes), the flow proceeds to the reversing step 307. The reversing step 307 is a step of reversing the wafer unit 211 before performing the second division step 304.

In the second embodiment, in the reversing step 307, the control unit 100 of the braking device 1 reverses the wafer unit 211 by the reversing unit 90 after releasing the fixation of the frame 208 by the fixing unit 10, and then fixes the frame 208 to the fixing unit 10. In the method of manufacturing a chip according to the second embodiment, after the reversing step 307, in the second division step 304, as illustrated in FIG. 20, the first pressing bar 60 presses the wafer 200 from the back surface 206 side via the sheet 207. In the method of manufacturing a chip according to the second embodiment, after the second division step 304 is performed along all the planned division lines 203, the expanding step 306 is performed.

In the method of manufacturing a chip and the braking device 1 according to the second embodiment, in the same manner as in the first embodiment, the pressing is performed from the front surface 202 side along the planned division line 203 in the first division step 302, and the pressing is performed from the back surface 206 side along the planned division line 203 in the second division step 304, whereby the ductile material layer 212 can be divided along the planned division line 203, and generation of burrs after the division can be suppressed. This provides an advantageous effect of being able to divide the ductile material layer 212 without impairing quality.

Note that, in the second embodiment, after the first division step 302 and the third division step 303 are performed for all the planned division lines 203, the reversing step 307 is performed, and then the second division step 304 is performed for all the planned division lines 203. Alternatively, in the present invention, the division may be performed for each planned division line 203 by sequentially repeating the first division step 302, the third division step 303, the reversing step 307, and the second division step 304.

### First Modification

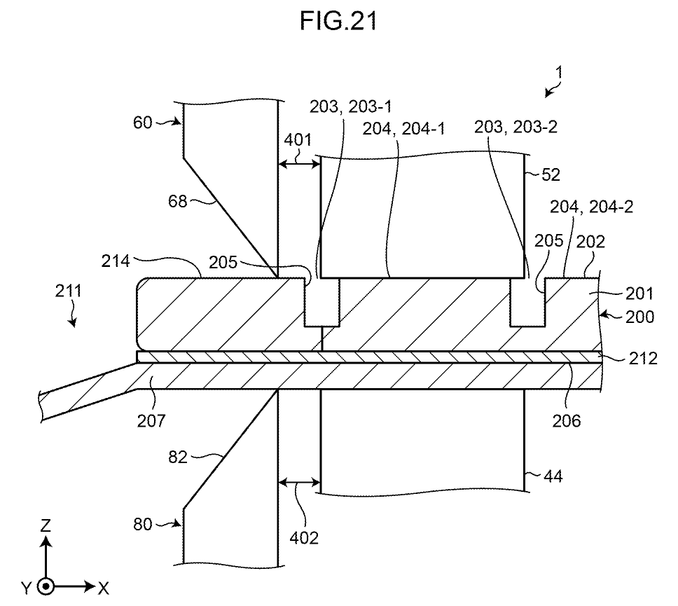

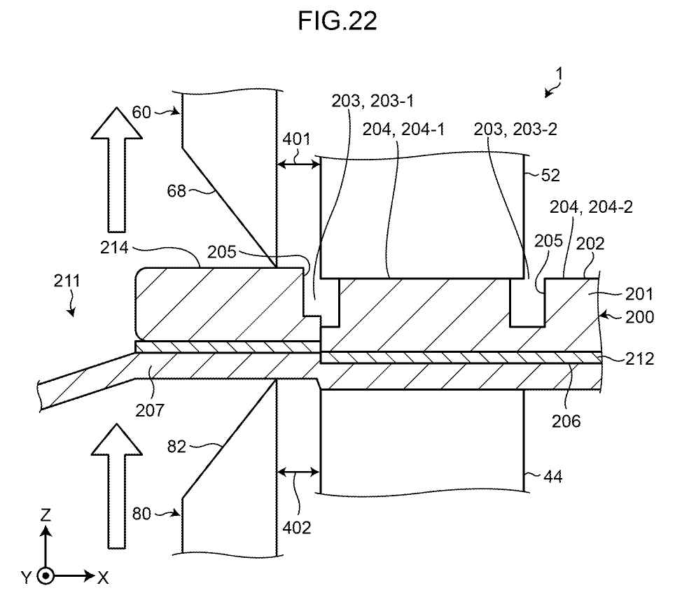

The method of manufacturing a chip according to a first modification is described with reference to the drawings. FIG. 21 is a diagram schematically illustrating, in a partial cross section, a main part in a state where the wafer is clamped between pressing bars in the second division step of the method of manufacturing a chip according to the first modification. FIG. 22 is a diagram schematically illustrating, in a partial cross section, a main part in a state where the wafer is pressed in the second division step of the method of manufacturing a chip according to the first modification. In FIGS. 21 and 22, the same parts as those in the first embodiment are denoted by the same reference numerals, and description thereof is omitted.

The method of manufacturing a chip according to the first modification is the same as that of the first embodiment except that the second division step 304 is different. In the first modification, in the first division step 302, the wafer 200 is pressed by the first pressing bar 60 in the same direction as in the first embodiment. In the first modification, in the second division step 304, as illustrated in FIG. 21, the region 214, which is the second region of the wafer unit 211, is clamped between the pair of pressing bars 60 and 80.

In the first modification, in the second division step 304, as illustrated in FIG. 22, in a state in which the region 214, which is the second region of the wafer unit 211, is clamped between the pair of pressing bars 60 and 80, the region 214 is pressed with the pressing bars 60 and 80 in a direction opposite to that in the first division step 302. That is, in the first modification, in the second division step 304, when performing the pressing with the second pressing bar 80, the first pressing bar 60 moves while maintaining a certain distance in accordance with the movement accompanying the pressing of the second pressing bar 80, while bringing the first pressing bar 60 into contact with the wafer 200 from the opposite side.

In this manner, in the first modification, in the second division step 304, while the device 204-1, which corresponds to the first region of the wafer unit 211, is clamped by the clamping members 44 and 52 along the first planned division line 203-1, the region 214, which is the second region of the wafer unit, is clamped by the pair of pressing bars 60 and 80, and then the clamping members 44 and 52 and the pair of pressing bars 60 and 80 are moved relative to each other in the thickness direction of the wafer 200.

In the method of manufacturing a chip according to the first modification, in the same manner as in the first embodiment, the pressing is performed from the front surface 202 side along the planned division line 203 in the first division step 302, and the pressing is performed from the back surface 206 side along the planned division line 203 in the second division step 304, whereby the ductile material layer 212 can be divided along the planned division line 203, and generation of burrs after the division can be suppressed. This provides an advantageous effect of being able to divide the ductile material layer 21 without impairing quality.

Further, in the method of manufacturing a chip according to the first modification, since the wafer 200 is clamped between the pressing bars 60 and 80 in the second division step 304, it is possible to prevent the wafer 200 from escaping in the bending direction, and a shear stress can be effectively added.

### Second Modification

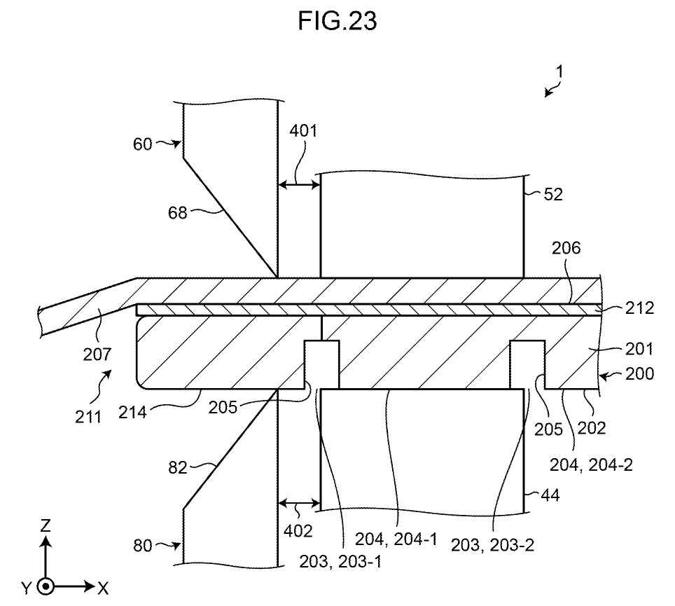

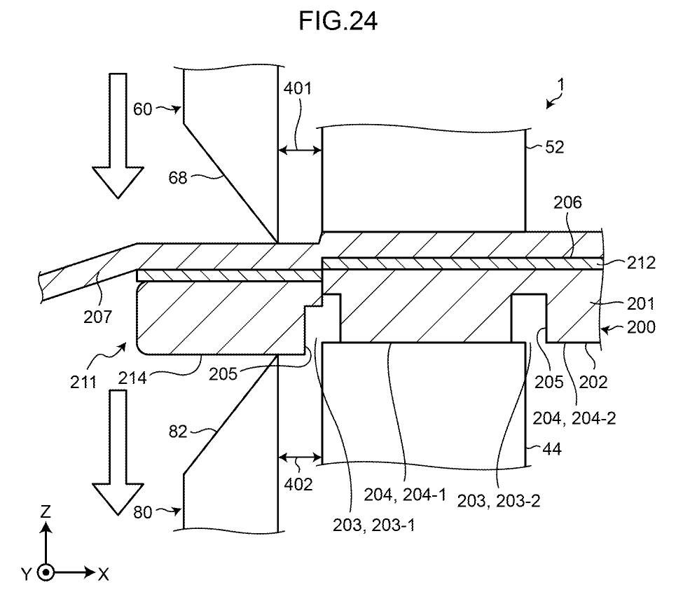

A method of manufacturing a chip according to a second modification is described with reference to the drawings. FIG. 23 is a diagram schematically illustrating, in a partial cross section, a main part in a state where the wafer is clamped between pressing bars in the second division step of the method of manufacturing a chip according to the second modification. FIG. 24 is a diagram schematically illustrating, in a partial cross section, a main part in a state where the wafer is pressed in the second division step of the method of manufacturing a chip according to the second modification. In FIGS. 23 and 24, the same parts as those in the second embodiment are denoted by the same reference numerals, and description thereof is omitted.

The method of manufacturing a chip according to the second modification is the same as that of the second embodiment except that the second division step 304 is different. In the second modification, in the first division step 302, the wafer 200 is pressed by the first pressing bar 60 in the same direction as in the first embodiment, the third division step 303 is performed, and then the reversing step 307 is performed. In the second modification, in the second division step 304, as illustrated in FIG. 23, the device 204-1, which corresponds to the first region of the wafer unit 211, is clamped by the clamping members 44 and 52, and the region 214, which is the second region of the wafer unit 211, is clamped between the pair of pressing bars 60 and 80.

In the second modification, in the second division step 304, as illustrated in FIG. 24, in a state in which the region 214, which is the second region of the wafer unit 211, is clamped between the pair of pressing bars 60 and 80, the region 214 is pressed with the pressing bars 60 and 80 in a direction opposite to the first division step 302. That is, in the second modification, in the second division step 304, when performing the pressing with the first pressing bar 60, the second pressing bar 80 moves while maintaining a certain distance in accordance with the movement accompanying the pressing of the first pressing bar 60, while bringing the second pressing bar 80 into contact with the wafer 200 from the opposite side.

In this manner, in the second modification, in the second division step 304, while the device 204-1, which is the first region of the wafer unit 211, is clamped by the clamping members 44 and 52 along the first planned division line 203-1, the region 214, which is second region of the wafer unit 211, is clamped by the pair of pressing bars 60 and 80, and then the clamping members 44 and 52 and the pair of pressing bars 60 and 80 are moved relative to each other in the thickness direction of the wafer 200.

In the method of manufacturing a chip according to the second modification, in the same manner as in the second embodiment, the pressing is performed from the front surface 202 side along the planned division line 203 in the first division step 302, and the pressing is performed from the back surface 206 side along the planned division line 203 in the second division step 304, whereby the ductile material layer 212 can be divided along the planned division line 203, generation of burrs after the division can be suppressed. This provides an advantageous effect of being able to divide the ductile material layer 212 without impairing quality.

Further, in the method of manufacturing a chip according to the second modification, since the wafer 200 is clamped between the pressing bars 60 and 80 in the second division step 304, it is possible to prevent the wafer 200 from escaping in the bending direction, and a shear stress can be effectively added.

### Third Modification

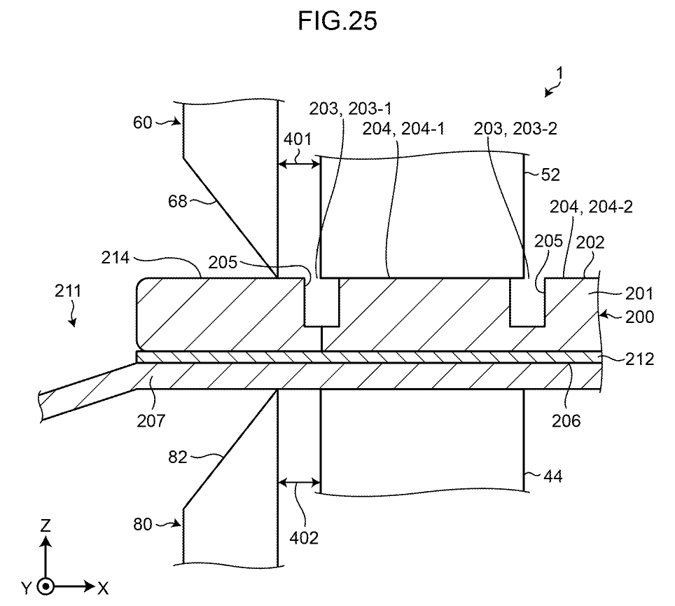

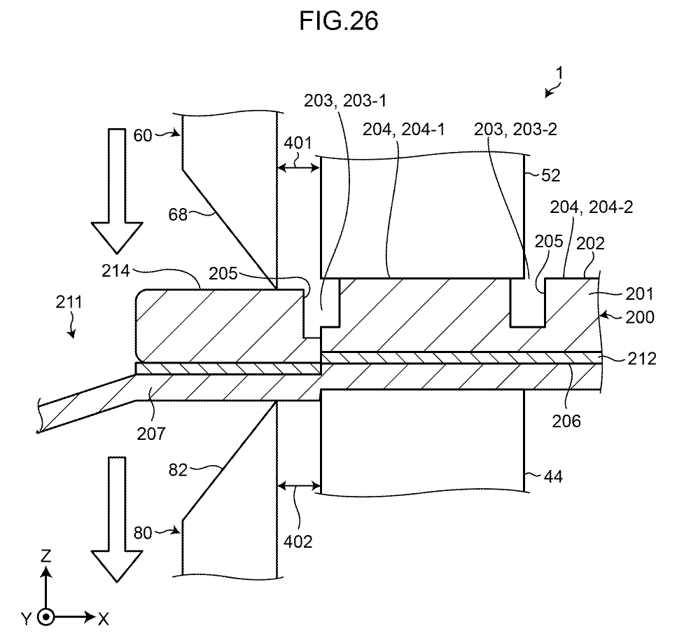

A method of manufacturing a chip according to a third modification is described with reference to the drawings. FIG. 25 is a diagram schematically illustrating, in a partial cross section, a main part in a state where the wafer is clamped between pressing bars in a second division step of the method of manufacturing a chip according to the third modification. FIG. 26 is a diagram schematically illustrating, in a partial cross section, a main part in a state where the wafer is pressed in the second division step of the method of manufacturing a chip according to the third modification. In FIGS. 25 and 26, the same parts as those in the first embodiment are denoted by the same reference numerals, and description thereof is omitted.

The method of manufacturing a chip according to the third modification is the same as that of the first embodiment except that the second division step 304 is different. In the third modification, in the first division step 302, the wafer 200 is pressed by the first pressing bar 60 in the same direction as in the first embodiment. In the third modification, in the second division step 304, as illustrated in FIG. 25, the device 204-1, which corresponds to the first region of the wafer unit 211, is clamped by the clamping members 44 and 52, and the region 214, which is the second region of the wafer unit 211, is clamped between the pair of pressing bars 60 and 80.

In the third modification, in the second division step 304, as illustrated in FIG. 26, in a state in which the region 214, which is the second region of the wafer unit 211, is clamped between the pair of pressing bars 60 and 80, the region 214 is pressed with the pressing bars 60 and 80 in a direction the same as that in the first division step 302 by the pressing bars 60 and 80. That is, in the third modification, in the second division step 304, when performing the pressing with the first pressing bar 60, the second pressing bar 80 moves while maintaining a certain distance in accordance with the movement accompanying the pressing of the first pressing bar 60, while bringing the second pressing bar 80 into contact with the wafer 200 from the opposite side.

In this manner, in the third modification, in the second division step 304, while the device 204-1, which corresponds to the first region of the wafer unit 211, is clamped by the clamping members 44 and 52 along the first planned division line 203-1, the region 214, which is the second region of the wafer unit 211, is clamped by the pair of pressing bars 60 and 80, and then the clamping members 44 and 52 and the pair of pressing bars 60 and 80 are moved relative to each other in the thickness direction of the wafer 200.

In the method of manufacturing a chip according to the third modification, similarly to the first modification, since the wafer 200 is clamped between the pressing bars 60 and 80 in the second division step 304, it is possible to prevent the wafer 200 from escaping in the bending direction. Thus, the shear stress can be effectively added to the wafer 200, the ductile material layer 212 can be divided along the planned division line 203, and generation of burrs after the division can be suppressed. This provides an advantageous effect of being able to the ductile material layer 212 without impairing the quality.

### Fourth Modification

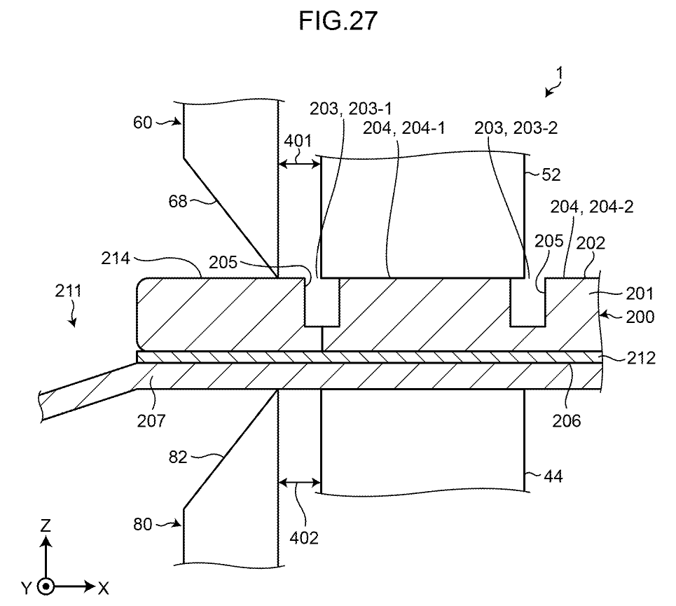

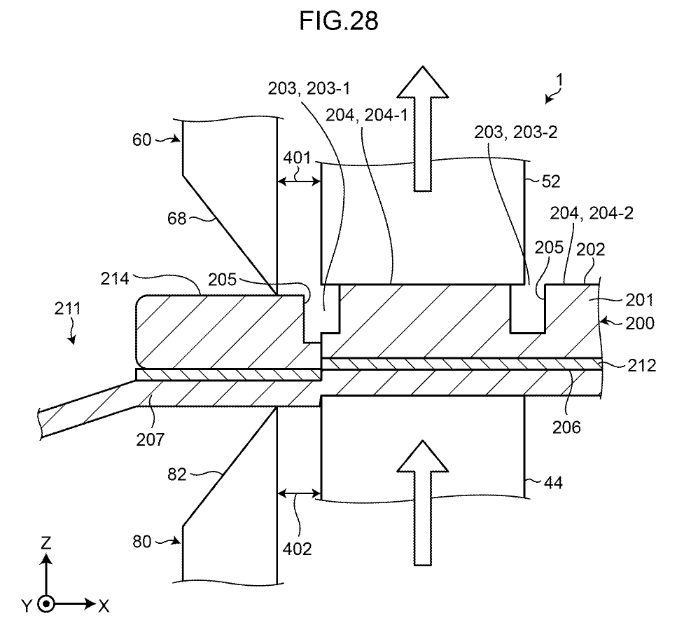

A method of manufacturing a chip according to a fourth modification is described with reference to the drawings. FIG. 27 is a diagram schematically illustrating, in a partial cross section, a main part in a state where the wafer is clamped between pressing bars in a second division step of the method of manufacturing a chip according to the fourth modification. FIG. 28 is a diagram schematically illustrating, in a partial cross section, a main part in a state where the clamping member is moved and the wafer is pressed by the pressing bar in the second division step of the method of manufacturing a chip according to the fourth modification. In FIGS. 27 and 28, the same parts as those in the first embodiment are denoted by the same reference numerals, and description thereof is omitted.

The method of manufacturing a chip according to the fourth modification is the same as that of the first embodiment except that the second division step 304 is different. In the fourth modification, in the first division step 302, the wafer 200 is pressed by the first pressing bar 60 in the same direction as in the first embodiment. In the fourth modification, in the second division step 304, as illustrated in FIG. 27, the device 204-1, which corresponds to the first region of the wafer unit 211, is clamped by the clamping members 44 and 52, the region 214, which is the second region of the wafer unit 211, is clamped between the pair of pressing bars 60 and 80.

In the fourth modification, in the second division step 304, as illustrated in FIG. 28, in a state in which the region 214, which is the second region of the wafer unit 211, is clamped between the pair of pressing bars 60 and 80, the clamping members 44 and 52 are moved together in the direction opposite to the pressing direction of the first pressing bar 60 in the first division step 302, whereby the region 214 is pressed with the pressing bars 60 and 80 in the same direction as in the first division step 302.

In this manner, in the fourth modification, in the second division step 304, while the device 204-1, which corresponds to the first region of the wafer unit 211, is clamped by the clamping members 44 and 52 along the first planned division line 203-1, the region 214, which is the second region of the wafer unit 211, is clamped by the pair of pressing bars 60 and 80, and then the clamping members 44 and 52 and the pair of pressing bars 60 and 80 are moved relative to each other in the thickness direction of the wafer 200.

In the method of manufacturing a chip according to the fourth modification, similarly to the first modification, since the wafer 200 is clamped between the pressing bars 60 and 80 in the second division step 304, it is possible to prevent the wafer 200 from escaping in the bending direction. Thus, the shear stress can be effectively added, the ductile material layer 212 can be divided along the planned division line 203, and generation of burrs after the division can be suppressed. This provides an advantageous effect of being able to divide the ductile material layer 212 without impairing the quality.

### Fifth Modification

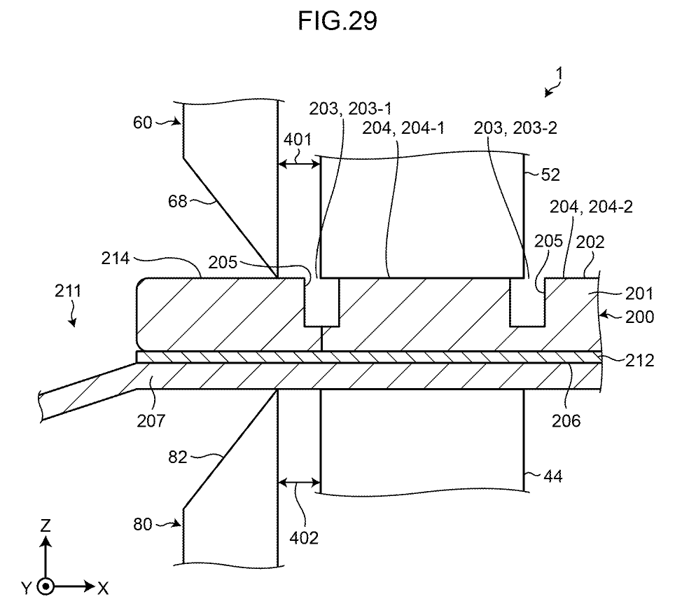

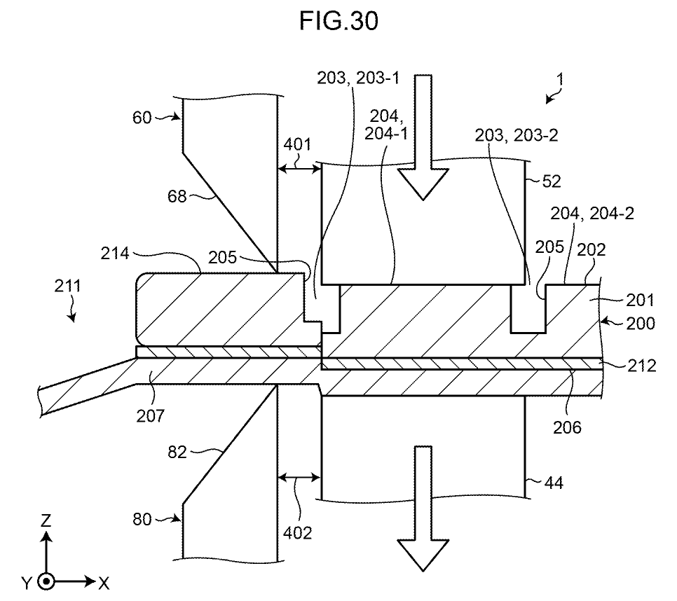

A method of manufacturing a chip according to a fifth modification is described with reference to the drawings. FIG. 29 is a diagram schematically illustrating, in a partial cross section, a main part in a state where the wafer is clamped between the pressing bars in the second division step of the method of manufacturing a chip according to the fifth modification. FIG. 30 is a diagram schematically illustrating, in a partial cross section, a main part in a state where the clamping member is moved and the wafer is pressed by the pressing bar in the second division step of the method of manufacturing a chip according to the fifth modification. In FIGS. 29 and 30, the same parts as those in the first embodiment are denoted by the same reference numerals, and description thereof is omitted.

The method of manufacturing a chip according to the fifth modification is the same as that of the first embodiment except that the second division step 304 is different. In the fifth modification, in the first division step 302, the wafer 200 is pressed by the first pressing bar 60 in the same direction as in the first embodiment. In the fifth modification, in the second division step 304, as illustrated in FIG. 29, the device 204-1, which corresponds to the first region of the wafer unit 211, is clamped by the clamping members 44 and 52, the region 214, which is the second region of the wafer unit 211, is clamped between the pair of pressing bars 60 and 80.

In the fifth modification, in the second division step 304, as illustrated in FIG. 30, in a state in which the region 214, which is the second region of the wafer unit 211, is clamped between the pair of pressing bars 60 and 80, the clamping members 44 and 52 are moved together in the same direction as the pressing direction of the first pressing bar 60 in the first division step 302, whereby the region 214 is pressed with the pressing bars 60 and 80 in the opposite direction to that in the first division step 302.

In this manner, in the fifth modification, in the second division step 304, while the device 204-1, which corresponds to the first region of the wafer unit 211, is clamped by the clamping members 44 and 52 along the first planned division line 203-1, the region 214, which is the second region of the wafer unit 211, is clamped by the pair of pressing bars 60 and 80, and then the clamping members 44 and 52 and the pair of pressing bars 60 and 80 are moved relative to each other in the thickness direction of the wafer 200.

In the method of manufacturing a chip according to the fifth modification, in the same manner as in the first modification, the pressing is performed from the front surface 202 side along the planned division line 203 in the first division step 302, and the pressing is performed from the back surface 206 side along the planned division line 203 in the second division step 304, whereby the ductile material layer 212 can be divided along the planned division line 203, and generation of burrs after the division can be suppressed. This provides an advantageous effect of being able to divide the ductile material layer 212 without impairing quality.

Further, in the method of manufacturing a chip according to the fifth modification, since the wafer 200 is clamped between the pressing bars 60 and 80 in the second division step 304, it is possible to prevent the wafer 200 from escaping in the bending direction, and a shear stress can be effectively added.

Note that the present invention is not limited to the above embodiments. That is, various modifications can be made without departing from the gist of the present invention.

Note that, in the above-described embodiment, an example is described in which the distance between the position pressed by the pressing bars 60 and 80 of the wafer 200 and the first planned division line is equal to the distances 400, 401, and 402 in the X-axis direction. However, in the present invention, the distance between the position pressed by the pressing bars 60 and 80 of the wafer 200 and the first planned division line may not be equal to the distances 400, 401, and 402 in the X-axis direction.

Further, in the present invention, in the method of manufacturing a chip, the second division step 304 may be performed without performing the third division step 303. In the present invention, a place where the pressing bars 60 and 80 press the wafer 200 in the first division step 302, the third division step 303, and the second division step 304 is not limited to the place described in the first embodiment and the second embodiment.

In addition, in the first embodiment and the second embodiment, the wafer 200 is configured with two layers of the base layer 201 and the ductile material layer 212, but in the present invention, the wafer 200 may include other layers in addition to the base layer 201 and the ductile material layer 212. In addition, in the first embodiment and the second embodiment described above, the term “the ductile material layer 212 side” and the term “the base layer 201 side” merely indicates which side relative to the midpoint of the wafer 200 in the thickness direction is referred to, during the breaking.

In addition, in the first embodiment and the second embodiment, the wafer 200 is pressed from the front surface 202 side in the first division step 302, the wafer 200 is pressed from the front surface 202 side in the third division step 303, and the wafer 200 is pressed from the back surface 206 side in the second division step 304. However, in the present invention, the wafer 200 may be pressed from the back surface 206 side in the first division step 302, the wafer 200 may be pressed from the back surface 206 side in the third division step 303, and the wafer 200 may be pressed from the front surface 202 side in the second division step 304.

The present invention provides the advantageous effect of being able to divide a ductile material layer without impairing quality.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method of manufacturing a chip by dividing a wafer having division starting points formed along planned division lines for sectioning a chip region where the chip is formed, along the planned division lines, the method comprising:
a first division step including
pressing, while clamping a first region of a wafer unit by a clamper along a first planned division line of the planned division lines, a second region of the wafer unit along the first planned division line from a back surface side of the wafer or from a front surface side opposite to the back surface side, the wafer unit including the wafer and a sheet fixed to a back surface of the wafer, the first region being on one side of the first planned division line, the second region being on an opposite side of the first planned division line; and
a second division step performed after the first division step, including
pressing the second region of the wafer unit along the first planned division line from the back surface side or from the front surface side that is different from that in the first division step, while clamping the first region of the wafer unit by the clamper along the first planned division line.

2. The method of manufacturing a chip according to claim 1, further comprising:
a third division step performed after the first division step and before the second division step, including
pressing the second region of the wafer unit at a position closer to the first planned division line than a position pressed in the first division step, from the back surface side or from the front surface side that is the same as in the first division step along the first planned division line, while clamping the first region of the wafer unit by the clamper along the first planned division line.

3. The method of manufacturing a chip according to claim 1, further comprising:
an expanding step of expanding the sheet of the wafer unit after the second division step.

4. The method of manufacturing a chip according to claim 1, further comprising:
a reversing step of reversing the wafer unit before the second division step.

5. The method of manufacturing a chip according to claim 1, wherein the wafer has
a base layer including the chip region, and
a ductile material layer made of a ductile material.

6. The method of manufacturing a chip according to claim 5, wherein the base layer of the wafer is made of silicon carbide.

7. A method of manufacturing a chip by dividing a wafer having division starting points formed along planned division lines for sectioning a chip region where the chip is formed, along the planned division lines, the method comprising:
a first division step including
pressing, while clamping a first region of a wafer unit by a clamper along a first planned division line of the planned division lines, a second region of the wafer unit along the first planned division line from a back surface side of the wafer or from a front surface side opposite to the back surface side along the first planned division line, the wafer unit including the wafer and a sheet fixed to a back surface of the wafer, the first region being on one side of the first planned division line, the second region being on an opposite side of the first planned division line; and
a second division step performed after the first division step, including
clamping the second region of the wafer unit by a pair of pressing bars, while clamping the first region of the wafer unit by the clamper along the first planned division line, and
relatively moving the clamper and the pair of pressing bars in a thickness direction of the wafer.

8. The method of manufacturing a chip according to claim 7, further comprising:
a third division step performed after the first division step and before the second division step, including
pressing the second region of the wafer unit at a position closer to the first planned division line than a position pressed in the first division step, from the back surface side or from the front surface side that is the same as in the first division step along the first planned division line, while clamping the first region of the wafer unit by the clamper along the first planned division line.

9. The method of manufacturing a chip according to claim 7, further comprising:
an expanding step of expanding the sheet of the wafer unit after the second division step.

10. The method of manufacturing a chip according to claim 7, further comprising:
a reversing step of reversing the wafer unit before the second division step.

11. The method of manufacturing a chip according to claim 7, wherein the wafer has
a base layer including the chip region, and
a ductile material layer made of a ductile material.

12. The method of manufacturing a chip according to claim 11, wherein the base layer of the wafer is made of silicon carbide.

13. A dividing device comprising:
a fixing unit that fixes a wafer unit, the wafer unit including a wafer in which planned division lines for sectioning a chip region are set and a sheet fixed to the wafer;
a detection unit that detects the planned division lines of the wafer of the wafer unit fixed by the fixing unit;
a pair of clamping bars that clamps a first region of the wafer unit along a first planned division line of the planned division lines detected by the detection unit, the first region being on one side of the first planned division line;
a first pressing bar that presses a second region of the wafer unit along the first planned division line from a front surface side, the second region being on an opposite side of the first planned division line; and
a second pressing bar that is a component different from the first pressing bar and presses the second region of the wafer unit along the first planned division line from a side opposite to the front surface side.

14. A dividing device comprising:
a fixing unit that fixes a wafer unit, the wafer unit including a wafer in which planned division lines for sectioning a chip region are set and a sheet fixed to the wafer;
a detection unit that detects the planned division lines of the wafer of the wafer unit fixed by the fixing unit;
a pair of clamping bars that clamps a first region of the wafer unit along a first planned division line of the planned division lines detected by the detection unit, the first region being on one side of the first planned division line;
a pressing bar that presses a second region of the wafer unit along the first planned division line, the second region being on an opposite side of the first planned division line; and
a reversing unit that reverses the wafer unit.
